(19) United States
(12) Patent Application Publication
(10) Pub. No.: US 2026/0299429 A1
(43) Pub. Date: Oct. 1, 2026

(54) OPTICAL SYSTEM, METHOD OF USE, AND METHOD OF FABRICATION

(71) Applicant: xLight Inc., Palo Alto, CA (US)

(72) Inventor: Christopher Neil Anderson, Palo Alto, CA (US)

(73) Assignee: xLight Inc., Palo Alto, CA (US)

(21) Appl. No.: 19/574,900

(22) Filed: Mar. 23, 2026

Related U.S. Application Data
(60) Provisional application No. 63/781,022, filed on Mar. 31, 2025.
(60) Provisional application No. 63/894,497, filed on Oct. 6, 2025.

(51) Int. Cl. H05G 2/00; G03F 7/00; G03F 7/20

(52) U.S. Cl. CPC H05G 2/009; G03F 7/2004; G03F 7/70033; G03F 7/70075; H05G 2/0086

(57) ABSTRACT

An optical system, method of use, and/or method of fabrication. The optical system preferably includes a vacuum vessel, one or more mirrors, and one or more support members. The method of use preferably includes receiving a light beam, creating a virtual focus, and delivering a light output. The method of fabrication preferably includes retrofitting an existing light source and/or fabricating an optical system using components designed for a existing light source.

### CROSS-REFERENCE TO RELATED APPLICATIONS

This application claims the benefit of U.S. Provisional Application No. 63/781,022, filed 31 Mar. 2025, and of U.S. Provisional Application No. 63/894,497, filed 6 Oct. 2025, each of which is herein incorporated in its entirety by this reference.

### TECHNICAL FIELD

This invention relates generally to the optics field, and more specifically to a new and useful optical system, method of use, and method of fabrication.

### BRIEF DESCRIPTION OF THE SEVERAL VIEWS OF THE DRAWINGS

FIG. 1A is a schematic cross-sectional representation of an embodiment of an optical system.

FIG. 1B is a schematic representation of an example of the optical system in use.

FIG. 2 is a schematic cross-sectional representation of an embodiment of mirror surfaces of the optical system.

FIGS. 3A-3C are a plan view, elevation view, and isometric view, respectively, of a specific example of cooling channels of the optical system.

FIGS. 4A-4B are schematic representations of a first and second example, respectively, of shadowed volumes within the optical system.

FIG. 5 is a schematic representation of a specific example of a portion of the optical system.

FIG. 6 is a schematic representation of a method of use for an optical system.

### DETAILED DESCRIPTION OF THE INVENTION

The following description of the preferred embodiments of the invention is not intended to limit the invention to these preferred embodiments, but rather to enable any person skilled in the art to make and use this invention.

### 1. Overview

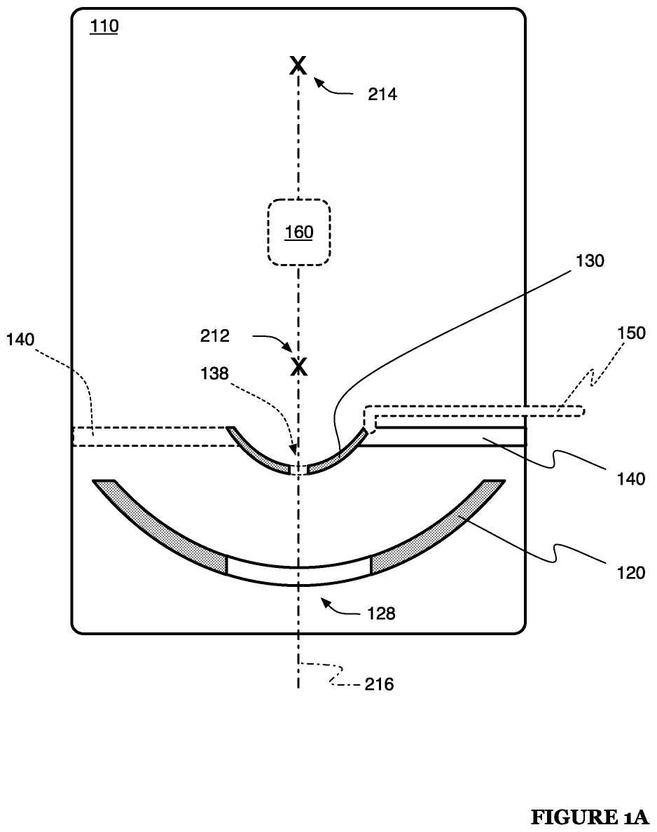

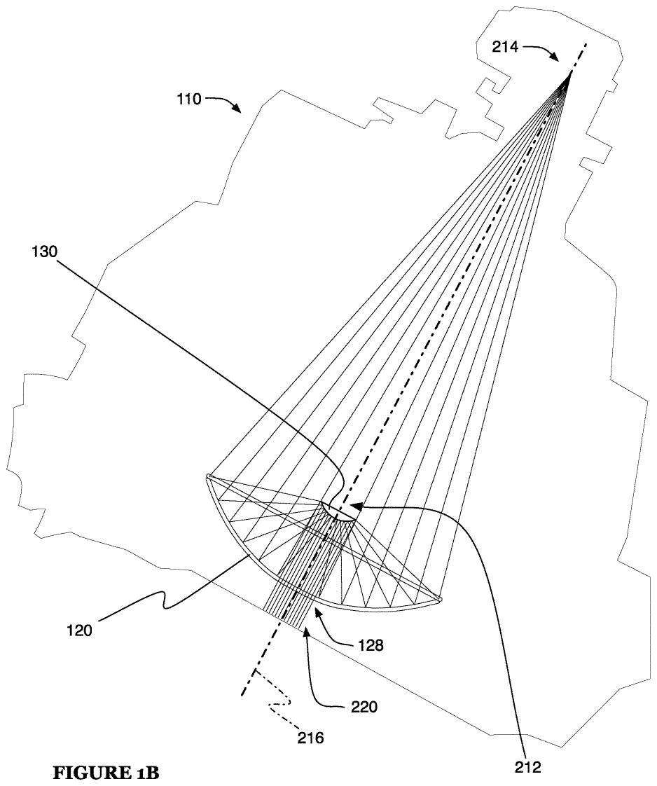

An optical system 100 preferably includes a vacuum vessel 110, one or more mirrors (preferably including a collector mirror 120 and a replicator mirror 130), and/or one or more support members 140, and can optionally include cooling lines 150 and/or a beam dump 160 (e.g., as shown by way of examples in FIGS. 1A and/or 1B). However, the system can additionally or alternatively include any other suitable elements in any suitable arrangement, and/or can have any other suitable functionality.

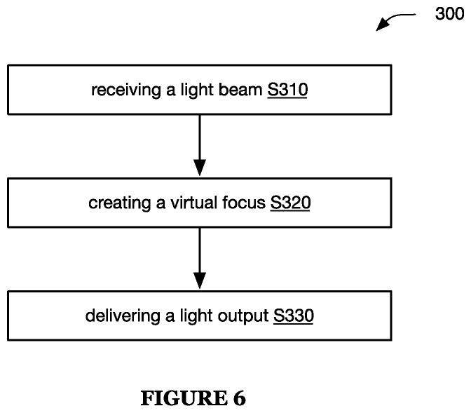

A method of use 300 for an optical system can include receiving a light beam S310, creating a virtual focus S320, and delivering a light output S330 (e.g., as shown in FIG. 6). The method can additionally or alternatively include any other suitable elements performed in any suitable manner.

The optical system 100 and method of use 300 preferably function to deliver extreme ultraviolet (EUV) light in a manner that simulates light emission from a source at (and/or near) a first point (e.g., by reflecting the EUV light such that it is divergent with a virtual focus at the first point). In some examples, the optical system can function as a retrofit for a laser-produced plasma (LPP) light source (e.g., commercially-available LPP light source), wherein the virtual focus simulates light emission by the plasma (e.g., located at and/or around the first point) of the LPP light source, preferably wherein the collector mirror of the optical system is substantially identical to a collector mirror of the LPP light source (and/or wherein any other suitable optical elements of the optical system are substantially identical to the analogous elements of the LPP light source). Additionally or alternatively, in some examples, the optical system can function independently of any LPP light source (e.g., as a standalone optical system for delivering light to one or more lithographic tools, metrology tools, and/or any other suitable tools). However, the optical system and/or method of use can additionally or alternatively have any other suitable function.

A method of fabrication for an optical system can include retrofitting an existing laser-produced plasma (LPP) light source (e.g., commercially-available LPP light source), fabricating an optical system using one or more components that are designed for (and/or identical to components of) an LPP light source, and/or any fabricating the optical system in any other suitable manner. The method of fabrication preferably functions to fabricate the optical system described herein, but can additionally or alternatively be used to fabricate any other suitable optical system.

The optical system 100 is preferably operable to perform the method of use described herein (e.g., the optical system performs the method of use), but can additionally or alternatively have any other suitable functionality and/or can additionally or alternatively perform any other suitable methods. The method of use is preferably performed using the optical system described herein, but can additionally or alternatively be performed using any other suitable systems.

In some examples, the optical system can include one or more elements (e.g., vacuum vessel, collector mirror, etc.) that are identical (or substantially identical) to those of a laser-produced plasma (LPP) light source and/or a lithographic scanner that includes and/or integrates with an LPP light source (e.g., a commercially-available LPP light source and/or scanner). In examples, the commercially-available lithographic scanner can be a standard-NA (e.g., 0.33 NA) EUV scanner such as an ASML NXE-series scanner (e.g., NXE: 3400, NXE: 3600, NXE: 3800, and/or any other suitable NXE-series scanner), a high-NA (e.g., 0.55 NA) EUV scanner such as an ASML EXE-series scanner (e.g., EXE: 5000, EXE: 5200, and/or any other suitable EXE-series scanner), a hyper-NA (e.g., 0.75 NA or greater) EUV scanner such as an ASML HXE-series scanner, optionally including and/or integrated with an ASML high-performance platform (HPP), and/or any other suitable commercially-available lithographic scanner from any suitable manufacturer; and/or the LPP light source can be a Cymer/ASML EUV light source, a Gigaphoton EUV light source, and/or any other suitable LPP light source. However, the optical system can additionally or alternatively be used with any other suitable lithographic scanner(s) and/or light source(s). In some variants, the optical system (e.g., different embodiments thereof) can be compatible with different lithographic scanner platforms (e.g., a standard-NA EUV scanner such as the ASML NXE series, a high-NA EUV scanner such as the ASML HPP series, and/or any other suitable scanner platform(s)). Different scanner platforms can have different mirror geometries, different intermediate focus specifications, and/or different étendue requirements. In some examples, the optical system can be adapted and/or adaptable for different platforms, such as by selecting a replicator mirror shape, position, and/or size appropriate for the particular platform. However, the optical system can additionally or alternatively be adapted for any other suitable platform(s).

### 2. Technical Advantages

Variants of the technology (e.g., the optical system and/or method of operation) can confer one or more advantages over conventional technologies.

First, variants of the technology can provide retrofit compatibility, such as by reuse of existing (designs and/or parts for) LPP collector mirrors, vacuum vessels, and/or downstream optics (e.g., field facet mirrors, pupil facet mirrors, etc.) without requiring redesign of the collector-to-scanner optical path. The virtual focus behind the replicator mirror (away from the collector mirror) can emulate light emission from a plasma at and/or near the virtual focus point (e.g., from the perspective of the collector mirror), which can enable seamless integration with existing lithography systems. In some examples, this compatibility can reduce implementation costs and/or development time compared to conventional approaches that may require complete system overhauls for use with different EUV source technologies.

Second, variants of the technology can additionally or alternatively enable enhanced power and/or polarization control through the use of free-electron laser (FEL) systems. An FEL can control output power by adjusting the average current of the electron beam traversing the undulators that cause lasing, which can circumvent the plasma physics limitations that constrain typical LPP output power. Additionally or alternatively, an FEL can control light output polarization based on undulator characteristics (e.g., direction of electron beam undulation), whereas typical LPP light sources produce substantially unpolarized light. In a specific example, this capability can enable higher average EUV power delivery, superior control of average EUV power delivery, and/or control of EUV polarization, providing greater flexibility and/or performance in lithography processes as compared with typical LPP light sources.

Third, variants of the technology can additionally or alternatively support placement of ancillary elements (e.g., mechanical supports, cooling lines, etc.) in shadowed volumes, such as wherein such elements can be arranged in volumes that are already expected (e.g., in a scanner design context) to be shadowed by elements (e.g., droplet generator, tin catch, etc.) typically present in LPP sources. This strategic placement can avoid additional throughput loss that might otherwise occur if these ancillary elements were arranged outside such shadowed volumes. For example, by utilizing existing shadowed volumes, the system can ensure acceptable light collection efficiency (e.g., avoiding or reducing throughput loss attributable to shadowing by the ancillary elements) while accommodating necessary support infrastructure.

However, further advantages can additionally or alternatively be conferred by variants of the technology disclosed herein.

### 3. System

### 3.1 Vacuum Vessel

The vacuum vessel 110 preferably functions to fluidly isolate a vessel interior from an ambient environment and/or to maintain the vessel interior at a reduced pressure (e.g., to prevent or reduce dissipation of EUV light within the vessel).

The light handled (e.g., received, reflected, output, etc.) by the optical system preferably has high photon energy, such as being EUV light (e.g., 13.5 nm, 6.7 nm, etc.), X-ray light, and/or any other suitable high-energy light, but can additionally or alternatively have any other suitable photon energy. In examples, the light can be X-ray light (e.g., 0.01-0.1 nm, 0.1-0.2 nm, 0.2-0.5 nm, 0.5-1 nm, 1-2 nm, 2-5 nm, 5 nm, 1 nm, 0.1 nm, etc.), UV light, preferably EUV light (e.g., 13.5 nm, 6.7 nm, 5-8 nm, 8-15 nm, 15-30 nm, 30-121 nm, etc.) but additionally or alternatively any other suitable UV light (e.g., 100-280 nm, 280-315 nm, 315-400 nm, etc.), and/or any other suitable light, but can additionally or alternatively have any other suitable photon energy (e.g., visible light such as light having a wavelength in the 400-750 nm range, infrared light such as light having a wavelength in the 0.75-15 μm range and/or the 15-1000 μm range, etc.); the wavelengths described herein refer to the photon wavelength in a vacuum (the ‘free-space photon wavelength’). The light is preferably substantially monochromatic (e.g., having a bandwidth less than 1, 0.5, 0.3, 0.2, 0.1 nm, or less, less than 10%, 5%, 2%, 1%, or less of the nominal or central wavelength, etc.), but can alternatively have any other suitable bandwidth.

The vacuum vessel preferably houses the other elements of the system (or any suitable subset of the elements). In some examples, the vacuum vessel can be identical (or substantially identical) to the vacuum vessel of a laser-produced plasma (LPP) light source and/or lithographic scanner, and/or can define an interior volume identical (or substantially identical) to that of the vacuum vessel of the LPP source and/or lithographic scanner. For example, the vacuum vessel can be a vacuum vessel of an ASML LPP source and/or lithographic scanner.

The vacuum vessel preferably integrates with (e.g., is mechanically connected to, shares an evacuated interior with, etc.) one or more lithographic tools (e.g., scanners). However, the vacuum vessel can additionally or alternatively be integrated with any other suitable systems.

The vessel interior can optionally contain (and/or be operable and/or configured to contain) one or more buffer gasses (and/or any other suitable gaseous species and/or other species). The buffer gas can include (e.g., be) hydrogen (H₂), helium (He), argon (Ar), and/or any other suitable gasses. In some examples, the vessel interior contains gaseous hydrogen at a partial pressure of about 0.1 to about 10 Pa (e.g., about 0.1, 0.2, 0.5, 1, 2, 5, and/or 10 Pa; 0.1-0.3, 0.3-1, 1-3, and/or 3-10 Pa; less than 0.1 Pa; greater than 10 Pa; etc.).

The vacuum vessel can optionally include and/or interface with a differential pumping system. The differential pumping system can maintain a pressure differential between the vessel interior and an external environment (e.g., a beamline of a free-electron laser, such as a beamline maintained at high or ultra-high vacuum during FEL operation). The differential pumping system can include one or more pumping stages, vacuum valves, and/or apertures. However, the vacuum vessel can additionally or alternatively include any other suitable pressure management systems.

In some embodiments, the vessel interior can define two or more pressure regions. In a first example, the vessel interior defines a first region and a second region, the first region and the second region separated (e.g., fluidly separated, partially fluidly separated, and/or conductance-limited) at or near the light output point 214 (e.g., at or near the intermediate focus). The first region preferably houses the collector mirror 120 and the replicator mirror 130 (e.g., the first region can correspond to a region that, in a corresponding LPP light source, would house the tin plasma and the collector mirror). The second region can be arranged on an opposing side of the light output point from the first region (e.g., housing one or more illumination optics such as a field facet mirror and/or a pupil facet mirror). The first region can be maintained at a first pressure (e.g., high vacuum, such as a pressure less than about 10⁻³ Pa, 10⁻⁴ Pa, 10⁻⁵ Pa, and/or 10⁻⁶ Pa), and the second region can be maintained at a second pressure, typically higher than the first pressure (e.g., containing a buffer gas, such as hydrogen; in examples, the buffer gas can be at a partial pressure of about 0.1 to about 10 Pa, less than 0.1 Pa, or greater than 10 Pa, and/or the overall pressure in the second region can be about 0.1 to about 10 Pa, less than 0.1 Pa, or greater than 10 Pa). In some examples, a conductance-limiting element (e.g., an aperture, an iris, and/or any other suitable conductance-limiting element) arranged at or near the light output point can separate the first region from the second region. However, the vessel interior can additionally or alternatively define any other suitable pressure regions in any suitable arrangement.

However, the system can additionally or alternatively include any other suitable vacuum vessel.

### 3.2 Mirrors

### 3.2.1 Collector Mirror.

The collector mirror 120 preferably functions to focus incoming light 220 at a light output point 214 (e.g., intermediate focus point). The collector mirror preferably includes a reflective surface 124 (e.g., concave reflective surface) and a collector body 126.

The reflective surface can bound the collector body (e.g., defining an exterior surface of the collector body). The collector mirror (e.g., the body thereof) can define one or more structural features (e.g., central hole 128, mounting interface(s), cooling channel(s), etc.).

The reflective surface 124 of the collector mirror is preferably concave (or substantially concave), but can additionally or alternatively have any other suitable shape (e.g., having concave regions along with convex and/or planar regions).

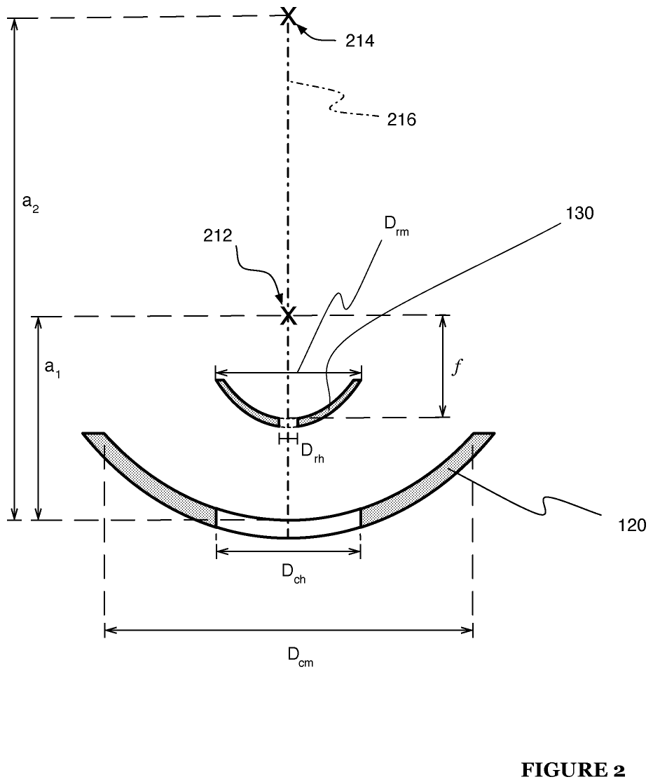

The reflective surface preferably defines a portion of a surface of rotation of a conic section (e.g., an ellipse, a parabola, a hyperbola, a circle, and/or any other suitable conic section), more preferably wherein the reflective surface is elliptical (or substantially elliptical). The reflective surface (e.g., elliptical surface) preferably defines a first focus at a first point 212 and a second focus at a light output point 214 (e.g., intermediate focus point), and preferably defines an optical axis 216 (e.g., through or substantially through the first and second foci, preferably wherein the optical axis is an axis of the conic section defined by the reflective surface), such as shown by way of example in FIG. 2. The surface of rotation is preferably defined by rotation of the conic section about an axis of the conic section (e.g., major axis of an ellipse), preferably the optical axis. In some embodiments, the reflective surface is a surface of rotation (e.g., about the optical axis, such as about an axis of the conic section, preferably about the major axis of the ellipse) of a portion of a conic section (e.g., ellipse); the portion of the conic section preferably does not include a vertex of the conic section (e.g., thereby defining a central hole at and around the vertex), such as wherein the portion is close to, but does not include, the vertex. The reflective surface is preferably elliptical, but can alternatively be parabolic, hyperbolic, spherical, aspheric, can define a surface of rotation (or a portion thereof) of any other suitable curves (e.g., one or more aspheric curves, polynomial curves, freeform curves, etc.), and/or can define any other suitable shape.

The reflective surface of the collector mirror preferably defines a perimeter (e.g., outer perimeter, defined along an edge of the surface farthest from the vertex of the conic section generatrix) that encircles (or substantially encircles) the optical axis. In some examples, the perimeter defines a circular shape, an elliptical shape, a rectilinear shape, a polygonal shape (e.g., hexagonal, octagonal, and/or any other suitable polygonal shape), an irregular shape, and/or any other suitable shape. The perimeter can include curved edges, straight edges, and/or any combination thereof. The perimeter can be planar (or substantially planar) or non-planar. However, the reflective surface can additionally or alternatively define any other suitable perimeter.

In some examples, the collector mirror can be identical (or substantially identical) to the collector mirror of a laser-produced plasma (LPP) light source (e.g., the same LPP light source as for the vacuum vessel). For example, the collector mirror can be (or be substantially identical to) a collector mirror of an ASML LPP source (e.g., Zeiss collector mirror for the ASML LPP source), preferably wherein the collector mirror is housed in a vacuum vessel of (or substantially identical to that of) the ASML LPP source.

In some variants, the collector mirror 120 can define a reflective surface 124 having a shape that differs from (e.g., is modified relative to) the collector mirror of the corresponding LPP light source (e.g., an LPP light source, such as a commercially-available LPP light source, having a vacuum vessel matching that of the system). For example, the collector mirror shape can be co-designed with the replicator mirror 130 shape (e.g., wherein the collector mirror shape and the replicator mirror shape are jointly selected and/or optimized) to optimize one or more characteristics of the output light at the light output point 214 and/or at one or more downstream optical elements (e.g., a field facet mirror). In some examples, the optimized characteristic can include an intensity distribution (e.g., intensity uniformity), an angular distribution, an étendue, a wavefront quality, and/or any other suitable optical characteristic; for example, the optimized characteristic can be a desired intensity profile (e.g., a substantially uniform intensity profile such as a flat-top intensity profile, a super-Gaussian intensity profile, and/or any other suitable intensity profile). In some such variants, the collector mirror can maintain the same (or substantially the same) overall dimensions (e.g., diameter, central hole diameter, and/or focal distances) and/or the same mechanical interfaces (e.g., mechanical support, cooling lines, etc.) as the collector mirror of the LPP light source, while defining a different surface figure (e.g., a modified curvature, an aspheric departure from the nominal elliptical surface, a freeform surface modification, and/or any other suitable surface figure modification). However, the collector mirror can additionally or alternatively define any other suitable reflective surface shape.

In one embodiment, the first point can be at (or substantially at) a tin plasma location (e.g., wherein, in the LPP source that uses an identical collector mirror, the tin plasma is generated at the tin plasma location), and/or the light output point can be the intermediate focus point (e.g., from which light is delivered to one or more lithographic tools such as scanners).

The collector mirror preferably defines a central hole 128 (e.g., surrounding, such as centered or substantially centered on, the axis of the elliptical surface). The central hole can function to allow an input light beam 220 to enter a region on the concave side of the collector mirror (e.g., from a source location on the convex side of the collector mirror, such as beyond the boundary of the vacuum vessel).

The input light beam 220 can originate from a free-electron laser (FEL), a synchrotron, a high-harmonic generation (HHG) source, and/or any other suitable light source. The light output of the light source is preferably coherent or partially coherent, but can additionally or alternatively have any other suitable coherence. The light output of the light source is preferably collimated or substantially collimated. However, the light output can alternatively be convergent or divergent, preferably only slightly convergent or divergent, such as having a divergence angle less than a threshold angle (e.g., about 0.01, 0.05, 0.1, 0.2, 0.5, 1, 2, 5, 0.01-0.05, 0.05-0.1, 0.1-0.2, 0.2-0.5, 0.5-1, 1-2, and/or 2-5 degrees, less than 0.01 degrees, and/or greater than 5 degrees), but alternatively having any other suitable divergence angle.

The light source can be connected to the vacuum vessel via a beamline (e.g., including one or more grazing-incidence mirrors, beam steering elements, and/or any other suitable optical transport elements), and/or can be connected in any other suitable manner.

In one embodiment, the input light beam originates from a free-electron laser. The free-electron laser can generate a substantially collimated beam of light (e.g., EUV light, X-ray light, and/or any other suitable high-energy light) and can direct the beam through the central hole of the collector mirror (e.g., along or substantially along the optical axis defined by the collector mirror). The free-electron laser can be located outside the vacuum vessel (e.g., in a separate facility, connected to the vacuum vessel via a beamline; for example, the vacuum vessel can be located in the ballroom of a semiconductor fabrication facility, and the beamline can run through a subfab region of the semiconductor fabrication facility to reach a region under or near the vacuum vessel). The free-electron laser can generate light having a wavelength in a range of 1 nm to 100 nm (e.g., about 13.5 nm, about 6.7 nm, etc.) and/or any other suitable wavelengths. However, the input light beam can additionally or alternatively originate from any other suitable light source and/or have any other suitable optical characteristics.

The input light beam preferably enters along (or substantially along) the axis of the elliptical surface of the collector (the optical axis), but can additionally or alternatively enter along any other suitable trajectory. In some examples, in which the collector mirror is identical, or substantially identical, to that used in an LPP source, the central hole can be a hole that functions, in the context of the LPP source, to allow ingress of a drive laser beam (e.g., to ionize tin droplets).

In one example, the reflective surface of the collector mirror is a surface of rotation of a portion of an ellipse (e.g., wherein the portion is rotated about the major axis of the ellipse to define the surface; wherein the portion does not include a vertex of the ellipse, thereby defining a central hole at and around the vertex; etc.), the reflective surface has a diameter of 600-750 mm (e.g., about 660 mm) and defines a central hole with a diameter of 75-125 mm (e.g., about 103 mm), a distance from the collector mirror vertex (located within the central hole, such that the reflective surface is not present at the mirror vertex) to the first point (e.g., one focus of the ellipse) is 200-250 mm (e.g., about 230 mm), and a distance from the collector mirror vertex to the light output point (e.g., the other focus of the ellipse) is 1300-1600 mm (e.g., 1400-1500 mm, about 1450 mm, etc.), such as shown by way of example in FIG. 2.

In further examples, the reflective surface of the collector mirror can have a diameter of 200-1000 mm (e.g., about 200 mm, about 300 mm, about 500 mm, about 660 mm, about 800 mm, about 1 m, 200-300, 300-500, 500-650, 650-800, and/or 800-1000 mm, etc.), less than 200 mm, or greater than 1 m; can define a central hole with a diameter of 20-200 mm (e.g., about 20 mm, about 30 mm, about 50 mm, about 75 mm, about 103 mm, about 150 mm, about 200 mm, 20-30, 30-50, 50-75, 75-100, 100-150, and/or 150-200 mm, etc.), less than 20 mm, or greater than 200 mm; can define a distance from the collector mirror vertex to the first point of 50-500 mm (e.g., about 50 mm, about 100 mm, about 200 mm, about 300 mm, about 500 mm, 50-100, 100-200, 200-300, and/or 300-500 mm), less than 50 mm, and/or more than 500 mm; and/or can define a distance from the collector mirror vertex to the light output point of 500-3000 mm (e.g., about 500 mm, about 800 mm, about 1200 mm, about 1600 mm, about 2000 mm, about 3000 mm, 500-800, 800-1200, 1200-1600, 1600-2000, and/or 2000-3000 mm, etc.), less than 500 mm, and/or greater than 3 m. However, the collector mirror can additionally or alternatively have any other suitable dimensions.

Further, the system can additionally or alternatively include any other suitable collector mirror in any suitable arrangement.

### 3.2.2 Replicator Mirror.

The replicator mirror 130 preferably functions to direct incoming light toward (e.g., to) the collector mirror 120 (e.g., simulating the divergence of light emerging from a plasma source); more preferably, the replicator mirror functions to direct the incoming light toward the collector mirror with divergence such that the light defines a virtual focus at or near the first point. The replicator mirror preferably includes a reflective surface 134 (e.g., convex reflective surface) and a replicator body 136.

The reflective surface 134 can bound the replicator body 136 (e.g., defining an exterior surface of the replicator body). The replicator body can define one or more structural features (e.g., a central hole 138, cooling channels 132, mounting interfaces, and/or any other suitable features).

The reflective surface of the replicator mirror is preferably convex (or substantially convex), but can additionally or alternatively have any other suitable shape.

The virtual image produced by the replicator mirror at or near the first point can have a far-field angular distribution that substantially matches a far-field angular distribution of a light source at the first point (e.g., a plasma source present in an LPP light source that uses a collector mirror with an identical or substantially identical shape and/or arrangement to the collector mirror of the optical system). In some examples, the virtual image can have an angular distribution that is accepted by downstream optical elements (e.g., the collector mirror, a field facet mirror, a pupil facet mirror, and/or any other suitable downstream optics) with substantially the same efficiency as light from a plasma source at the first point. The étendue of the virtual image can be within the étendue acceptance of the downstream optical elements (e.g., wherein the étendue is less than about 0.1, 0.3, 1, 3, 10, 30, 100, 0.1-1, 1-10, and/or 10-100 mm² sr, etc.; alternatively greater than 10 mm² sr and/or within any other suitable etendue range). The replicator mirror is preferably arranged on (e.g., centered, or substantially centered, on and aligned, or substantially aligned, with) the axis (“optical axis”) of the collector mirror's elliptical surface (e.g., wherein the replicator mirror surface and the collector mirror surface define collinear or substantially collinear axes).

The reflective surface of the replicator mirror preferably defines a perimeter (e.g., outer perimeter, defined along an edge of the surface farthest from the vertex of the conic section generatrix) that encircles (or substantially encircles) the optical axis. In some examples, the perimeter defines a circular shape, an elliptical shape, a rectilinear shape, a polygonal shape (e.g., hexagonal, octagonal, and/or any other suitable polygonal shape), an irregular shape, and/or any other suitable shape. The perimeter can include curved edges, straight edges, and/or any combination thereof. The perimeter can be planar (or substantially planar) or non-planar. However, the reflective surface can additionally or alternatively define any other suitable perimeter.

The replicator mirror surface preferably creates a virtual image at (and/or near) the first point (e.g., for an input light beam reflected by the convex surface of the replicator mirror). Accordingly, the convex reflective surface preferably follows (or substantially follows) a surface of rotation of a conic section (e.g., an ellipse, a parabola, a hyperbola, a circle, and/or any other suitable conic section). The reflective surface of the replicator mirror (e.g., a conic section generatrix thereof) preferably defines: a replicator vertex; a replicator focus (e.g., at or near the first point); and/or a replicator axis (e.g., through its vertex and its focus). The replicator axis is preferably collinear (or substantially collinear) with the optical axis defined by the collector mirror (e.g., as shown in FIG. 2), but can alternatively have any other suitable orientation. The surface of rotation is preferably defined by rotation of the conic section about an axis of the conic section, preferably the replicator axis described above but alternatively any other suitable axis. In some embodiments, the reflective surface is a surface of rotation (e.g., about the replicator axis, such as about an axis of the conic section) of a portion of a conic section (e.g., parabola); the portion of the conic section preferably does not include a vertex of the conic section (e.g., thereby defining a central hole 138 at and around the vertex), such as wherein the portion is close to, but does not include, the vertex. The reflective surface is preferably parabolic, but can alternatively be elliptical, hyperbolic, spherical, aspheric, can define a surface of rotation (or a portion thereof) of any other suitable curves (e.g., one or more aspheric curves, polynomial curves, freeform curves, etc.), and/or can define any other suitable shape.

In some variants, the conic section type and/or other characteristics can be determined based on the focus condition of the input light beam. A position and shape of the replicator mirror can be determined based on an intersection of an input light beam geometry and a desired output light cone geometry. In some examples, the position of the replicator mirror along the optical axis can be determined by: defining a desired virtual image location (e.g., at or near the first point); determining one or more input beam characteristics (e.g., convergence characteristic, such as collimated, convergent, or divergent, along with the associated divergence angle; and/or any other suitable beam characteristics); and selecting a conic section (or other suitable generatrix for the reflective surface) and a position along the optical axis such that the convex reflective surface produces a virtual image at or near the desired location, given the input beam characteristic. However, the position and shape of the replicator mirror can additionally or alternatively be determined by any other suitable method. To achieve the desired virtual image at the first point, the conic section preferably has a first focus at the first point and a second focus at the focus point of the input light beam. In a first example, in which the input light beam is collimated, the conic section is preferably a parabola, with its focus at the first point and its axis collinear with (e.g., centered on) the input light beam, wherein the focus point of the collimated input light is at infinity along the parabola axis. In a second example, in which the input light is convergent, the conic section is preferably elliptical, with a first focus at the first point and a second focus at the input light focus point. In a third example, in which the input light is divergent, the conic section is preferably hyperbolic, with a first focus at the first point and a second focus at the input light focus point.

In some examples (e.g., in which the input light is only slightly uncollimated), a parabolic mirror surface (e.g., analogous to that described above regarding the first example) can be used in place of an elliptical or hyperbolic surface. For example, if the input light is divergent (e.g., slightly divergent), a parabolic replicator mirror (and its focus point) can be moved slightly closer to the collector mirror such that the focus is slightly closer to the collector than the first point is. Analogously, if the input light is convergent (e.g., slightly convergent), a parabolic replicator mirror (and its focus point) can be moved slightly farther from the collector mirror such that the focus is slightly farther from the collector than the first point is. Alternatively, the parabolic mirror can remain in the same location as for collimated light, despite the non-collimated (e.g., slightly non-collimated) nature of the input light. Although the use of a parabolic mirror with uncollimated input light will not perfectly create a virtual image at the first point, slight deviations from collimation of the input light will typically result in only slight deviations from the desired virtual image position, which, in some examples, can be within the tolerances of the lithographic tools that will accept the light at the intermediate focus point.

However, the replicator mirror can additionally or alternatively define any other suitable reflective surfaces.

The reflective surface can substantially define a surface of rotation of a curve about the optical axis. The curve can be a conic section (e.g., a parabola, an ellipse, a hyperbola, a circle, and/or any other suitable conic section). In alternative embodiments, the curve can be an aspheric curve (e.g., deviating from a conic section), a polynomial curve, a freeform curve, a curve optimized for aberration correction, and/or any other suitable curve. Any such curve can define a vertex at or near the optical axis. The surface of rotation of the curve can define the convex reflective surface (or a portion thereof). However, the convex reflective surface can additionally or alternatively define any other suitable shape.

In alternative embodiments, the convex reflective surface can define an aspheric surface (e.g., deviating from a conic section of revolution), a freeform surface (e.g., lacking rotational symmetry), a polynomial surface (e.g., defined by a polynomial equation in two or more variables), a surface optimized for aberration correction (e.g., correcting for coma, astigmatism, spherical aberration, and/or any other suitable aberrations), and/or any other suitable surface. Any such surface can define a vertex at or near the optical axis. However, the convex reflective surface can additionally or alternatively define any other suitable shape.

In some embodiments, the reflective surface 134 of the replicator mirror can define a shape selected to modify an intensity distribution of the reflected light. For example, the reflective surface shape can be selected to convert (e.g., by itself; in concert with one or more other reflective surfaces such as that of the collector mirror, which, in examples, can be an elliptical mirror, can be co-designed with the replicator mirror to achieve the desired conversion, and/or can have any other suitable shape; etc.) an input light beam having a first intensity profile (e.g., a Gaussian intensity profile, a non-uniform intensity profile, and/or any other suitable intensity profile) into reflected light having a second intensity profile (e.g., a substantially uniform intensity profile such as a flat-top intensity profile, a super-Gaussian intensity profile, and/or any other suitable intensity profile) at one or more downstream optical elements (e.g., at a field facet mirror, a pupil facet mirror, and/or any other suitable downstream optics). In some examples, the reflective surface can define a freeform surface, an aspheric surface, and/or any other suitable surface shape configured to redistribute the intensity of the input light beam across the reflected light cone. The intensity distribution modification can be achieved by the replicator mirror alone and/or in combination with one or more other optical elements of the system (e.g., the collector mirror 120). However, the reflective surface of the replicator mirror can additionally or alternatively define any other suitable shape for any other suitable purpose.

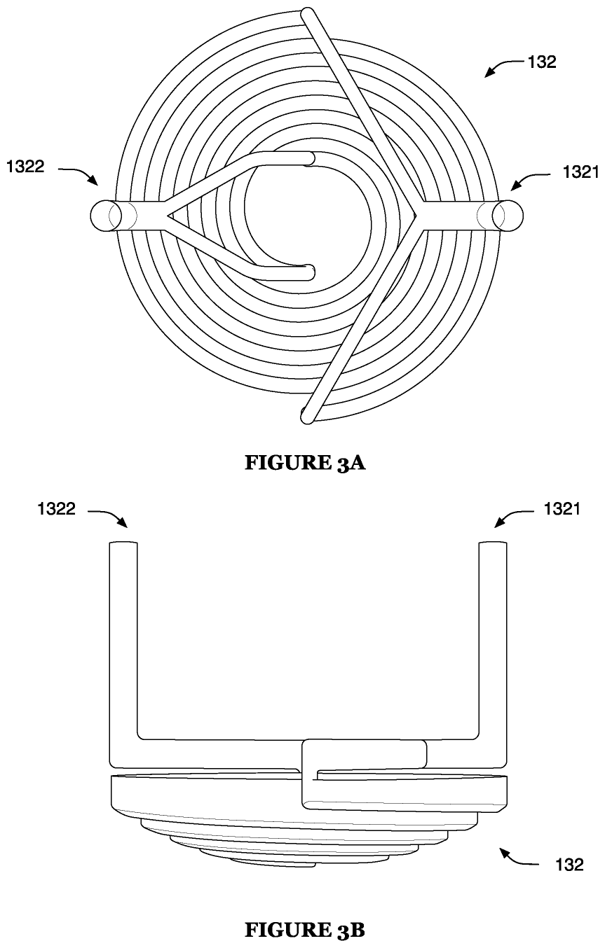

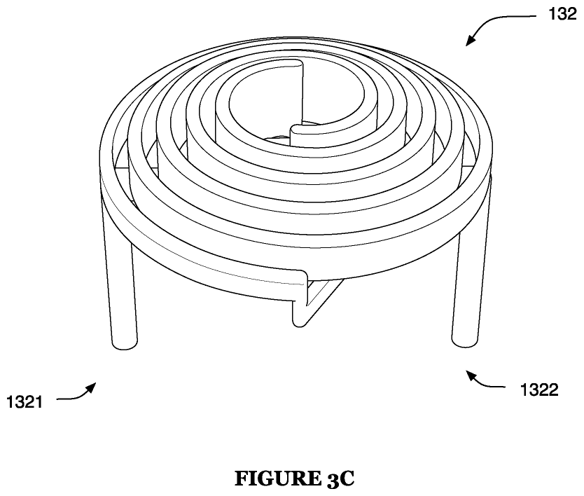

The replicator mirror can include one or more cooling channels 132. The cooling channels preferably route coolant fluid (e.g., from an input port 1321 to an output port 1322) through a path (or manifold) such that the coolant fluid is thermally coupled to the mirror surface. For example, the replicator mirror can define one or more spiral channels arranged on the concave side of the mirror surface, wherein the channels follow (or approximately follow) the curvature of the mirror surface (e.g., as shown in FIGS. 3A-3C). However, the replicator mirror can additionally or alternatively include any other suitable cooling channels.

The replicator mirror can optionally define one or more holes 138 (e.g., a central hole, such as described above regarding the reflective surface). The hole is preferably a thru-hole (e.g., the hole penetrates both the reflective surface and the replicator body), but can alternatively be a blind hole (e.g., a hole that does not extend through the entire replicator body, and/or a hole having a depth less than a thickness of the replicator body), such as wherein the hole is defined through the reflective surface of the replicator mirror, but not necessarily through the entire thickness of the replicator mirror body.

In some embodiments, the replicator hole size (e.g., the size of a central hole defined at or approximately at replicator vertex) can be determined based on one or more design considerations (e.g., bounds).

In some such embodiments, the replicator hole size can be determined (and/or bounded) based on the collector hole, such as wherein a bound on the replicator hole size can be determined based on the region of the surface of rotation of the replicator conic section generatrix that would reflect light of the input light beam back out the central hole of the collector (as opposed to reflecting the light onto the reflective surface of the collector). For example, the angle αᵣₕ subtended by the replicator hole, from a focus of the replicator mirror (e.g., from the first point), can be bounded based on an angle α_{ch} subtended by the central hole of the collector from the first point. Assuming the small-angle approximation applies, αᵣₕ=Dᵣₕ/f and α_{ch}=D_{ch}/a₁, where Dᵣₕ is a diameter of the replicator hole, f is a focal length of the replicator generatrix conic section from the replicator vertex to the replicator focus, D_{ch} is a diameter of the collector hole, and a₁ is a distance from the collector vertex to the first point; equivalently, a ratio of the replicator hole diameter to the collector hole diameter can be bounded by a ratio of the focal length to the distance a₁.

In a first embodiment, the replicator hole preferably does not exceed (or substantially exceed) the region of the surface of rotation of the replicator conic section generatrix that would reflect light of the input light beam back out the central hole of the collector. Accordingly, in this embodiment, αᵣₕ is preferably less than or equal to ach; for example, αᵣₕ can be approximately equal to (e.g., slightly less than, or alternatively, no more than slightly greater than) α_{ch}.

However, if the replicator hole is smaller than the bound described above, in some examples, the reflective surface near the center of the replicator mirror can redirect input light back through the central hole of the collector (e.g., as uncontrolled stray light); in some such examples, it may be preferable to instead route this light to a beam dump (e.g., via the replicator hole). Accordingly, in a second embodiment, the replicator hole is preferably no smaller than the region of the surface of rotation of the replicator conic section generatrix that would reflect light of the input light beam back out the central hole of the collector, meaning that αᵣₕ is preferably greater than or equal to ach; for example, αᵣₕ can be approximately equal to (e.g., slightly greater than, or alternatively, no more than slightly less than) α_{ch}.

In some examples (e.g., in which the aspect ratios of the collector and replicator mirrors are similar, such as wherein a ratio of the focal length of the replicator conic section to a diameter of the replicator mirror is approximately equal to a ratio of the distance from the collector to the first point to a diameter of the collector mirror), this bound can be approximated based on ratios between the hole diameters and overall mirror diameters. For example, a ratio of the replicator hole diameter to the replicator mirror diameter (Dᵣₕ/Dᵣₘ) can be bounded relative to (e.g., less than, approximately equal to, greater than, no more than slightly greater than, no less than slightly less than, etc.) a ratio of the collector hole diameter to the collector mirror diameter (D_{ch}/D_{cm}), such as wherein Dᵣₕ/Dᵣₘ≈D_{ch}/D_{cm}.

Additionally or alternatively, in some embodiments, the replicator hole size can be determined (and/or bounded) based on the overall size of the replicator mirror (e.g., based on the region shadowed by the replicator mirror with respect to light reflected by the collector mirror toward the light output point). The replicator body can block (shadow) some collector-reflected light converging toward the light output point. If the replicator hole is smaller than a shadow bound, then all input light that passes through the replicator hole (rather than being reflected by the replicator) corresponds to optical paths from the virtual source at the replicator focus that would be blocked by the replicator mirror after reflection by the collector mirror; accordingly, a replicator hole smaller than this shadow bound typically introduces no additional throughput loss (above the loss incurred by the replicator shadowing). This shadow bound can be expressed as

$${D}_{r h} \leq \frac{{D}_{r m} {fa}_{2}}{{a}_{1} ( {a}_{2} - {a}_{1} + f )}$$

where Dᵣₘ is a diameter of the replicator reflective surface and a₂ is a distance from the collector vertex to the light output point. Typically, this bound will be larger (e.g., more permissive) than the bound based on collector hole size. Accordingly, it may be preferable to use the collector hole-based bound as a lower bound (e.g., to prevent light reflection back out through the collector hole) and to use the shadow bound as an upper bound (e.g., to ensure that the replicator hole does not reduce light throughput). Note that, in some examples, this bound can be expanded further based on shadowing by other elements of the optical system (e.g., elements other than the replicator mirror that are arranged between the collector mirror and the light output point) and/or by elements of a corresponding LPP light source (e.g., elements that would be present in an LPP light source having the same or substantially the same collector mirror as the optical system and that would be arranged between the collector mirror and the light output point in such an LPP light source).

Further (e.g., with respect to all bounds described herein, or any suitable subset thereof), in some examples, it may be preferable to exceed (e.g., slightly exceed, such as by no more than a threshold amount) such bounds.

However, the central hole of the replicator mirror can alternatively have any other suitable size. Further, the replicator mirror can additionally or alternatively define any other suitable holes having any suitable positions, sizes, shapes, and/or orientations.

Alternatively, in some examples, the replicator mirror does not include a central hole (e.g., wherein the convex reflective surface extends to the optical axis or substantially to the optical axis), or the central hole of the replicator mirror is smaller (e.g., substantially smaller) than the lower bound described above. In such examples, the mirror can reflect a portion of the input light beam back out through the central hole of the collector. This light reflected back out through the central hole of the collector will typically be divergent and can be used and/or discarded in any suitable manner (e.g., directed to a beam dump using optics arranged past the concave side of the collector mirror, absorbed at a beam dump arranged around the input light beam beyond the convex side of the collector mirror, allowed to dissipate, etc.).

In one example, the reflective surface of the replicator mirror is a surface of rotation of a portion of a parabola (e.g., wherein the portion is rotated about the parabola axis to define the surface; wherein the portion may or may not include the parabola vertex, such as wherein a mirror with no hole preferably includes the vertex, whereas a mirror with a central hole preferably does not include the vertex, as the vertex lies within the central hole; etc.), the reflective surface has a diameter of 75-125 mm (e.g., about 100 mm) and optionally defines a central hole such as a hole with a diameter of 15-20 mm (e.g., 16-18 mm, about 17 mm, etc.), and a distance from the replicator mirror vertex (in examples in which the replicator mirror includes a central hole, the mirror vertex is located within the hole, and so the reflective surface is not present at the mirror vertex) to the first point (e.g., the focus of the parabola) is 25-45 mm (e.g., 30-35 mm, about 33 mm, etc.), such as shown by way of example in FIG. 2.

In some embodiments, the replicator mirror can include two or more mirror portions (e.g., multiple portions of the same surface of rotation, multiple portions arranged to collectively define the convex reflective surface, and/or any other suitable arrangement of portions, wherein each defines a different portion of the surface of rotation of the conic section). In some embodiments, the optical system can include two or more replicator mirrors (e.g., arranged adjacent to one another to collectively define the convex reflective surface, and/or any other suitable configuration). However, the optical system can additionally or alternatively include any other suitable number and/or arrangement of replicator mirrors.

However, the system can additionally or alternatively include any other suitable replicator mirror.

### 3.2.3 Mirror Properties.

The collector mirror and/or replicator mirror (and/or any other suitable mirrors of the optical system) can share one or more characteristics (e.g., having reflective surfaces of the same or similar compositions as each other, same or similar surface condition as each other, etc.), and/or can differ with regard to one or more characteristics.

In some embodiments, each reflective surface (or any suitable subset thereof) can include a respective multilayer coating. The multilayer coating can include one or more layers of molybdenum, silicon, ruthenium, beryllium, lanthanum, boron, boron carbide, molybdenum silicide, titanium dioxide, carbon, and/or any other suitable materials. In examples, the multilayer coating can include alternating layers of molybdenum and silicon (Mo/Si), alternating layers of ruthenium and silicon (Ru/Si), alternating layers of molybdenum and beryllium (Mo/Be), alternating layers of lanthanum and boron (La/B), alternating layers of lanthanum and boron carbide (La/B₄C), and/or any other suitable alternating layers. The multilayer coating can include interlayer materials such as boron carbide (B₄C), carbon (C), molybdenum silicide (MoSi₂), and/or any other suitable interlayer materials. The multilayer coating can include a capping layer including ruthenium (Ru), titanium dioxide (TiO₂), carbon (C), and/or any other suitable capping material. The multilayer coating can include approximately 20 to 100 bilayer pairs (e.g., about 20, about 30, about 40, about 50, about 60, about 80, about 100, 20-30, 30-40, 40-50, 50-60, 60-80, and/or 80-100 bilayer pairs, etc.), less than 20, and/or greater than 100 bilayer pairs, with a bilayer period of approximately 5 to 10 nm (e.g., about 5.0 nm, about 6.0 nm, about 6.5 nm, about 6.9 nm, about 7.0 nm, about 8.0 nm, about 10.0 nm, 5.0-6.0, 6.0-6.5, 6.5-7.0, 7.0-8.0, and/or 8.0-10.0 nm, etc.), less than 5 nm, and/or greater than 10 nm. However, the reflective surfaces can additionally or alternatively include any other suitable coatings.

Each mirror (or any suitable subset thereof) can include a respective substrate. The substrate can include silicon, aluminum alloy (e.g., RSA-6061), silicon carbide (SiC), beryllium (Be), Zerodur, fused silica, ultra-low expansion (ULE) glass, and/or any other suitable substrate material. Further, the mirror can include a buffer layer and/or an adhesion layer (e.g., including chromium (Cr), titanium (Ti), tantalum (Ta), and/or any other suitable buffer/adhesion material) arranged between the substrate and the multilayer coating. However, the mirrors can additionally or alternatively include any other suitable materials.

Each reflective surface (or any suitable subset thereof) can have a surface figure error of less than 0.01 μm, 0.03 μm, 0.1 μm, 0.3 μm, 1 μm, 2 μm, 5 μm, 10 μm, 30 μm, 100 μm, 300 μm, and/or any other suitable figure error. The surfaces can have a slope error of less than 1 urad, 10 urad, 50 urad, 100 urad, 500 urad, 1000 urad, 5000 urad, and/or any other suitable slope error. The surfaces can have a surface roughness (e.g., root-mean-square roughness) of less than 0.01 nm, 0.1 nm, 0.5 nm, 1 nm, 5 nm, 10 nm, and/or any other suitable roughness.

In some embodiments, the optical system can exhibit polarization-dependent behavior. The reflectivity of the reflective surfaces can vary based on a polarization state of the reflected light (e.g., transverse electric (TE) polarization, transverse magnetic (TM) polarization, and/or any other suitable polarization state). The reflectivity can vary based on an angle of incidence of the light on the reflective surface. In some examples, the replicator mirror and the collector mirror can provide azimuthal averaging of the polarization-dependent reflectivity (e.g., wherein light reflected at different azimuthal positions on the reflective surfaces experiences different polarization conditions, such that an average over all azimuthal positions results in a substantially uniform polarization response). In some examples, one or more of the reflective surfaces can include a graded multilayer coating (e.g., wherein the multilayer period varies across the surface to compensate for angle-of-incidence variations). However, the optical system can additionally or alternatively manage polarization effects in any other suitable manner.

However, the mirrors can additionally or alternatively have any other suitable properties.

### 3.3 Support Members

The support members preferably function to mechanically support the replicator mirror (and/or mechanically support any other suitable elements, such as the coolant lines). The system can include one or more support members mechanically connected to the replicator mirror (e.g., connecting the mirror to the vacuum vessel, such as an interior wall thereof, and/or to any other suitable structures).

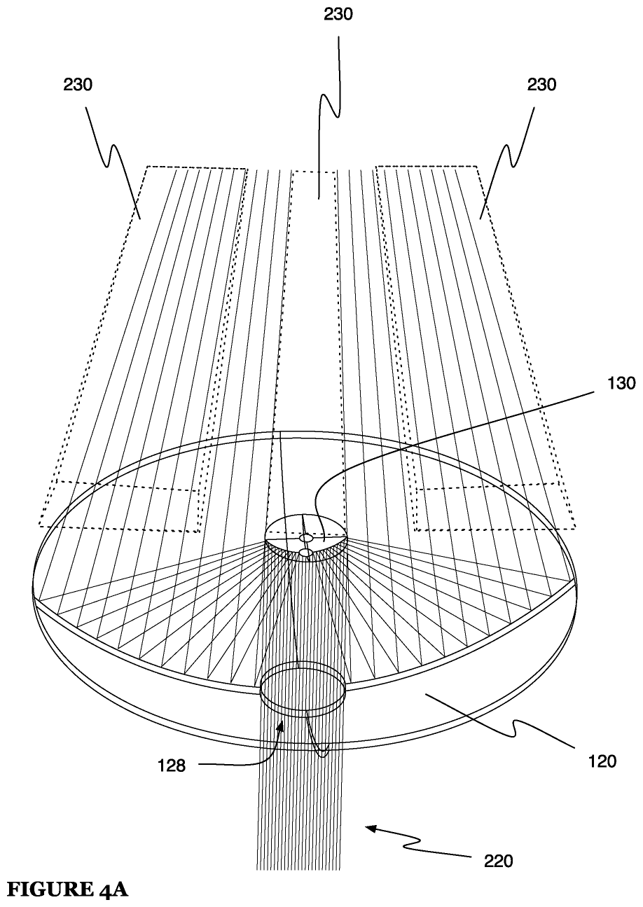

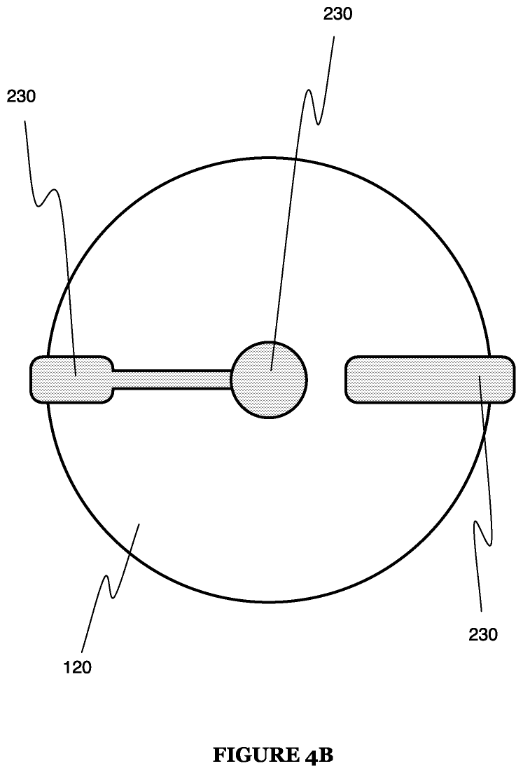

The support members are preferably arranged within (or substantially within, partially within, etc.) a shadowed volume 230 corresponding to one or more volumes within the LPP source described above, through which EUV light does not travel from the collector mirror to the intermediate focus point (e.g., wherein UV light does not reach the point within the shadowed volume, wherein UV light reaches the point within the shadowed volume but does not reach the intermediate focus point from that light, etc.). For example, the shadowed volume can include one or more volumes that, in the LPP source described above, would be shadowed by one or more elements such as the tin droplet generator and/or the tin catch (e.g., elements arranged on opposing sides of the tin plasma location), and/or can include one or more volumes that are shadowed by other elements of the actual system (e.g., the replicator lens), such as shown by way of examples in FIGS. 4A and/or 4B.

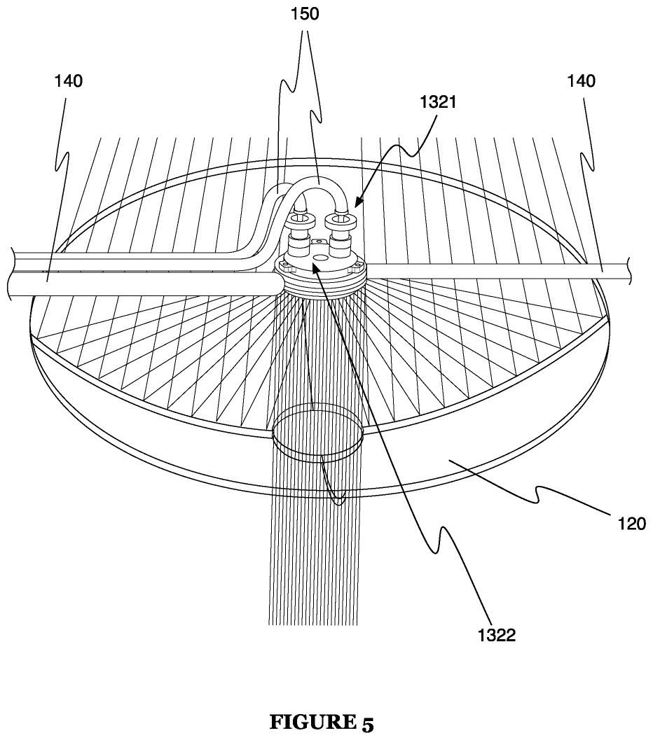

The support members preferably extend from beyond the edge of the collector mirror (e.g., from an interior wall of the vacuum vessel) to the replicator mirror (e.g., extending through the shadowed volume). In a first variant, the system includes a cantilevered support member (e.g., within the shadowed volume, such as within a volume that in the LPP source would be shadowed, in part or in whole, by the tin droplet generator). In a second variant, the system includes two support members extending outward from the replicator mirror, preferably in opposing (or substantially opposing) directions (e.g., as shown in FIG. 5). For example, the system can include a first support member arranged within a volume that, in the LPP source described above, would be shadowed (in part or in whole) by the tin droplet generator, and can include a second support member that, in the LPP source described above, would be shadowed (in part or in whole) by the tin catch.

In additional variants, the system can include a tripod support structure (e.g., three support members extending from the vacuum vessel to the replicator mirror, such as at approximately equal angular spacing about the optical axis), a ring mount (e.g., a ring structure connected to the vacuum vessel, with one or more spokes extending from the ring to the replicator mirror), a spider mount (e.g., a plurality of thin support members extending radially from the replicator mirror to the vacuum vessel), a flexure mount (e.g., including one or more compliant elements that flex to accommodate thermal expansion and/or vibration), and/or any other suitable support structure(s). The support members can be arranged within the shadowed volume described above, and/or can be arranged in any other suitable manner.

However, the system can additionally or alternatively include any other suitable support members having any suitable arrangement.

### 3.4 Cooling Lines

The cooling lines can function to provide coolant fluid (e.g., water) to the replicator mirror and/or to any other suitable elements of the system. The cooling lines are preferably arranged within (or substantially within) the shadowed volume described above, and/or within (or substantially within) a volume shadowed by one or more other elements of the system (e.g., shadowed by the support members), but can additionally or alternatively have any other suitable arrangement.

In one example, the system includes two cooling lines that transport cooling fluid to, and from, the replicator mirror, respectively (e.g., to the input port of the cooling channels thereof, and from the output port of the cooling channels thereof), such as transporting the coolant fluid between the replicator mirror and a chiller heat exchanger and/or other suitable coolant fluid receptacle (e.g., arranged outside the vacuum vessel), such as to form a cooling loop for the replicator mirror.

However, the system can additionally or alternatively include any other suitable cooling lines in any suitable arrangement.

Additionally or alternatively, the replicator mirror can include radial cooling channels (e.g., extending from a central region to a peripheral region of the mirror), fractal cooling channels (e.g., branching from a main channel into progressively smaller sub-channels), and/or any other suitable cooling channels defining any suitable patterns and/or arrangements. The replicator mirror can additionally or alternatively be cooled by one or more heat pipes, by jet impingement cooling, by radiative cooling, and/or by any other suitable cooling mechanism(s). However, the replicator mirror can additionally or alternatively be cooled by any other suitable method.

### 3.5 Beam Dump

The beam dump can function to accept (e.g., and absorb) input light that does not reach the collector mirror (e.g., input light that passes through the central hole of the replicator mirror). In one example, the beam dump is arranged beyond the concave side of the replicator mirror (wherein the replicator mirror is arranged between the collector mirror and the beam dump), preferably wherein the beam dump is arranged along (e.g., centered on) a central axis defined by the input light beam.

However, the system can additionally or alternatively include any other suitable beam dump.

In examples, the beam dump can be water-cooled, gas-cooled, radiatively cooled, and/or can employ any other suitable thermal management. In some examples, the beam dump can be substantially identical to a beam dump of a laser-produced plasma (LPP) light source (e.g., a beam dump configured to absorb a drive laser beam in the LPP light source). However, the beam dump can additionally or alternatively have any other suitable configuration.

In a laser-produced plasma (LPP) light source having one or more elements (e.g., collector mirror, vacuum vessel, etc.), EUV light originates at a plasma (e.g., tin plasma) within the vacuum vessel (e.g., at or near the first point) and radiates outward toward the collector mirror. The replicator mirror, positioned between the first point and the collector mirror such as described herein, would typically block a substantial portion of this outward-radiating EUV light before the light reaches the collector mirror. Accordingly, in examples in which the replicator mirror is added to an LPP light source (with an arrangement relative to the collector mirror analogous to that described herein regarding its arrangement within the optical system), the replicator mirror would typically block a significant portion (in some examples, all or substantially all) of the plasma-generated EUV light that would otherwise reach the collector mirror. Therefore, a person of ordinary skill in the art would understand that adding the replicator mirror to a conventional LPP light source in the position described herein would substantially reduce the EUV light collected by the collector mirror, degrading LPP light source performance, and so would not be motivated to add the replicator mirror such as described herein to a conventional LPP light source. The optical system described herein can avoid this issue because the light enters the vacuum vessel through the collector hole (e.g., from a free-electron laser or other external light source) and reflects from the replicator mirror back toward the collector mirror (e.g., with the first point serving as a virtual focus location, not as a location of a physical light-emitting plasma).

Additionally or alternatively, in some examples, one or more mechanical support structures for the replicator mirror (e.g., support members arranged within shadowed volumes, as described herein) may interfere with, and/or occupy space that would otherwise be occupied by, one or more components of a conventional LPP light source (e.g., a tin droplet generator, a tin catch, and/or any other suitable LPP-specific components). Accordingly, in some examples, accommodating the mechanical support structure for the replicator mirror within the vacuum vessel can require removing, relocating, and/or redesigning one or more such LPP-specific components.

Further, the system can additionally or alternatively include any other suitable elements having any suitable arrangement and/or functionality.

### 3.6 Specific Example

A specific example of the optical system is described below. In this specific example, the reflective surface of the collector mirror defines an elliptical surface having a diameter of about 660 mm and a central hole with a diameter of about 103 mm. The elliptical surface defines a first focus (the first point) at a first distance a₁ of about 230 mm from the collector vertex and a second focus (the light output point or intermediate focus point) at a second distance a₂ of about 1450 mm from the collector vertex. The collector mirror defines an optical axis through the first and second foci (e.g., through or substantially through the collector vertex, the first point, and the light output point).

In this specific example, the reflective surface of the replicator mirror defines a parabolic surface having a diameter of about 100 mm. The parabolic surface defines a replicator vertex and defines a replicator focus at a focal length f of about 33 mm from the replicator vertex (e.g., at or near the first point). The replicator mirror is arranged on the optical axis between the collector mirror and the first point, with the replicator focus at or near the first point.

In this specific example, the replicator mirror can optionally define a central hole. The central hole size can be determined based on one or more bounds.

A first bound on the replicator hole size can be determined based on the angle subtended by the replicator hole from the replicator focus relative to the angle subtended by the collector hole from the first point. In this example, using the small-angle approximation, Dᵣₕ≥14.8 mm. This bound can serve as a lower bound on the replicator hole size (e.g., to prevent light reflection back out through the collector hole, such as wherein this light is instead routed to a beam dump).

A second bound on the replicator hole size can be determined based on the shadow cast by the replicator body on collector-reflected light converging toward the light output point. In this example, this shadow bound can be expressed as Dᵣₕ≤16.6 mm. This shadow bound is larger (e.g., more permissive) than the first bound.

Accordingly, in this specific example, the replicator hole diameter is preferably within the range of about 14.8 mm to about 16.6 mm (e.g., about 15 mm, about 16 mm, about 17 mm, 14.8-16.6 mm, and/or any other suitable diameter within or approximately within this range). For example, the replicator mirror can define a central hole with a diameter of about 17 mm (e.g., 16-18 mm), which is approximately equal to the shadow bound (e.g., slightly exceeding the shadow bound, such as by no more than a threshold amount).

In a variation of this specific example, the vessel interior defines a first region housing the collector mirror and the replicator mirror, and a second region arranged on an opposing side of the light output point from the first region (e.g., housing one or more illumination optics, such as a field facet mirror and/or pupil facet mirror). A conductance-limiting iris having a diameter of about 2-10 mm (e.g., about 5 mm) is arranged at or near the light output point, limiting fluid flow between the first and second regions while allowing EUV light to propagate through the iris between the regions. The first region is maintained at high vacuum (e.g., at a pressure of about 10⁻³ to about 10⁻⁵ Pa) by one or more vacuum pumps (e.g., turbomolecular pumps). The second region contains a hydrogen buffer gas at a partial pressure of about 0.2 to about 0.4 Pa (e.g., about 2 to about 3 millitorr). The beamline connecting the light source to the vacuum vessel can maintain a pressure gradient from the light source to the first region of the vessel interior (e.g., wherein the light source is maintained at ultra-high vacuum, whereas the first region is maintained at high vacuum).

However, the optical system can additionally or alternatively have any other suitable dimensions, arrangements, and/or configurations.

### 3.7 Definitions

As used herein, ‘encircle’ (and variants such as ‘encircles’ and ‘encircling’) refers to a perimeter, boundary, or edge that extends around (e.g., surrounds, at least partially surrounds, and/or bounds) a point, axis, or region, regardless of the shape of the perimeter. For example, a circular perimeter, an elliptical perimeter, a rectilinear perimeter, a polygonal perimeter (e.g., square, hexagonal, octagonal, and/or any other suitable polygon), an irregular perimeter, and/or any other suitable perimeter shape can ‘encircle’ a point or axis. The perimeter can include curved edges, straight edges, and/or any combination thereof.

As used herein, the ‘vertex’ of a curve refers to a point of maximum (or alternatively, minimum) curvature of the curve. In some examples, the collector mirror defines a concave reflective surface that substantially defines a surface of rotation of a curve about the optical axis, the curve defining a vertex at or near the optical axis. In some examples, the replicator mirror defines a convex reflective surface that substantially defines a surface of rotation of a curve about the optical axis, the curve defining a vertex at or near the optical axis. The curve is preferably symmetric about the optical axis (i.e., the axis of rotation). However, the curve can additionally or alternatively have any other suitable shape.

As used herein, “a portion of a surface of rotation” can refer to a surface of rotation of a portion of a curve (e.g., taking a finite arc of a two-dimensional curve and rotating the arc about an axis to produce a three-dimensional surface). Additionally or alternatively, “a portion of a surface of rotation” can refer to a finite, bounded region of a surface of rotation (e.g., taking a full surface of rotation and selecting a bounded region thereof). In some examples, a surface of rotation of a portion of a curve and a bounded region of the corresponding full surface of rotation produce equivalent surfaces (e.g., an annular region centered on the axis of rotation). In some examples, a surface of rotation of a portion of a curve and a bounded region of the corresponding full surface of rotation can produce different surfaces (e.g., when the region is bounded by a non-circular perimeter, and/or when the region excludes the vertex region asymmetrically). As used herein, “a portion of a surface of rotation” encompasses both a surface of rotation of a portion of a curve and a bounded region of a full surface of rotation. The portion can be bounded by one or more planes (e.g., planes orthogonal to the axis of rotation, planes at oblique angles to the axis of rotation, and/or any other suitable planes), by curved surfaces, by irregular boundaries, and/or by any other suitable boundaries. The portion can define a contiguous region of the surface of rotation, or can alternatively define two or more non-contiguous regions of the surface of rotation. The portion can include or exclude a vertex region. In some examples, the portion defines an annular shape with a central hole proximate to the axis of rotation. The portion can extend symmetrically or asymmetrically about the vertex.

As used herein, “substantially defining a surface of rotation” (and/or analogous variants such as “substantially defines a surface of rotation”) can include surfaces that deviate from an ideal surface of rotation by less than a threshold figure error (e.g., about 0.01 micrometers, 0.03 micrometers, 0.1 micrometers, 0.3 micrometers, 1 micrometer, 3 micrometers, 10 micrometers, 30 micrometers, 100 micrometers, 300 micrometers, 0.01-0.1, 0.1-1, 1-10, 10-100, and/or 100-1000 micrometers, etc.) and/or a threshold relative error (e.g., about 0.01, 0.03, 0.1, 0.3, 1, 3, 0.01-0.1, 0.1-1, and/or 1-3% of a characteristic dimension defined by the corresponding mirror, such as diameter, focal length, etc.). In some examples, the surface can define a slope error of less than a threshold slope error (e.g., about 1 microradian, 3 microradians, 10 microradians, 30 microradians, 100 microradians, 300 microradians, 1000 microradians, 3000 microradians, 1-10, 10-100, 100-1000, and/or 1000-10,000 microradians, etc.). However, “substantially defining a surface of rotation” can additionally or alternatively be interpreted in any other suitable manner.

As used herein, a first element or feature (e.g., a virtual focus, a physical location, and/or any other suitable element or feature) can be “substantially at” a point (e.g., “substantially at the first point,” “substantially at the first focus,” and/or substantially at any other suitable point) if the first element or feature is at the point or displaced from the point by less than a threshold displacement (e.g., about 0.05 mm, 0.1 mm, 0.2 mm, 0.5 mm, 1 mm, 2 mm, 5 mm, 10 mm, 20 mm, 50 mm, 0.05-0.5, 0.5-5, and/or 5-50 mm, etc.). In some examples, the displacement can be less than a threshold percentage of a characteristic dimension of the system (e.g., less than about 0.1%, 0.2%, 0.5%, 1%, 2%, 5%, 10%, 0.1-1, and/or 1-10% of a focal length, a mirror diameter, a distance from a mirror vertex to the point, and/or any other suitable characteristic dimension). In some examples, the displacement can be comparable to, less than, or no more than a threshold multiple of (e.g., 1.1, 1.2, 1.5, 2, 3, 5, 1-1.2, 1.2-1.5, 1.5-2, 2-3, and/or 3-5 times greater than, etc.) a spatial extent of a plasma region of a laser-produced plasma EUV source (e.g., wherein the plasma region is defined as a region with significant EUV light emission) that uses a collector mirror substantially identical to the collector mirror of the optical system (e.g., the plasma region spatial extent being in a range of approximately 0.1 mm to 1 mm). However, “substantially at” a point can additionally or alternatively be interpreted in any other suitable manner.

As used herein, a first element or feature (e.g., a light beam, a direction of propagation, and/or any other suitable element or feature) can be “substantially along” an axis (e.g., “substantially along the optical axis” and/or any other suitable axis) if the first element or feature is along the axis or deviates from the axis by less than a threshold angular deviation (e.g., about 0.01 degrees, 0.05 degrees, 0.1 degrees, 0.2 degrees, 0.5 degrees, 1 degree, 2 degrees, 5 degrees, 0.01-0.1, 0.1-1, and/or 1-10 degrees, etc.). In some examples, the angular deviation can correspond to a lateral offset at a reference element (e.g., at the replicator mirror, at the collector mirror, and/or at any other suitable reference element) of less than a threshold offset (e.g., about 0.01 mm, 0.05 mm, 0.1 mm, 0.5 mm, 1 mm, 2 mm, 5 mm, 0.01-0.1, 0.1-1, and/or 1-10 mm, etc.). In some examples, the angular deviation can correspond to a displacement of a downstream feature (e.g., a virtual focus) comparable to or less than a spatial extent of a plasma region of a laser-produced plasma EUV source. However, “substantially along” an axis can additionally or alternatively be interpreted in any other suitable manner.

As used herein, a first element or feature (e.g., a beam dump, a mirror, a light output point, and/or any other suitable element or feature) can be “substantially on” an axis (e.g., “substantially on the optical axis” and/or any other suitable axis) if the first element or feature is on the axis or offset from the axis by less than a threshold offset distance (e.g., about 0.1 mm, 0.5 mm, 1 mm, 2 mm, 5 mm, 10 mm, 20 mm, 0.1-1, 1-10, and/or 10-30 mm, etc.). In some examples, the offset can be less than a threshold percentage of a characteristic dimension (e.g., about 1%, 2%, 5%, 10%, 20%, 1-5%, and/or 5-20% of a diameter of a hole through a mirror, a diameter of a reflective surface, and/or any other suitable reference dimension). However, “substantially on” an axis can additionally or alternatively be interpreted in any other suitable manner.

As used herein, a first component (e.g., a collector mirror, a field facet mirror, a vacuum vessel, and/or any other suitable component) can be “substantially identical” to a second component (e.g., a corresponding standard component of an LPP light source and/or lithographic scanner, and/or any other suitable component) if the first component can be used interchangeably with the second component without redesigning other components of a system that includes the second component. In some examples, substantially identical can include components that share the same optical prescription, the same mounting interface geometry, and/or the same outer dimensions, but that differ in features such as the presence or absence of a hole, the size of a hole, surface coatings, surface quality, substrate material, cooling channels, and/or any other suitable features. In some examples, substantially identical can include components that differ in one or more dimensions by less than a threshold percentage (e.g., about 1%, 2%, 5%, 10%, 20%, 1-5%, and/or 5-20%, etc.) of the corresponding dimension of the second component. However, “substantially identical” can additionally or alternatively be interpreted in any other suitable manner.

As used herein, a second arrangement can be substantially congruent with a first arrangement if the second arrangement can be superimposed on the first arrangement with positional deviations of less than a threshold positional deviation (e.g., about 0.1 mm, 0.5 mm, 1 mm, 2 mm, 5 mm, 10 mm, 0.1-1 mm, and/or 1-10 mm, etc.) and/or angular deviations of less than a threshold angular deviation (e.g., about 0.01 degrees, 0.05 degrees, 0.1 degrees, 0.5 degrees, 1 degree, 2 degrees, 5 degrees, 0.01-0.1, 0.1-1, and/or 1-10 degrees, etc.). In some examples, the second arrangement can be substantially congruent with the first arrangement if corresponding elements of the two arrangements share the same position and orientation to within manufacturing tolerances, assembly tolerances, and/or alignment tolerances of the corresponding components.

As used herein, “slightly” (e.g., “slightly convergent,” “slightly divergent,” “slightly uncollimated,” “slightly exceed a bound,” “slightly less than,” “slightly greater than,” and/or any other usage of “slightly” herein) refers to a deviation from a reference condition (e.g., from collimation, from a bound, from a threshold, and/or from any other suitable reference condition) that is small relative to the reference condition and/or small relative to a characteristic dimension or parameter of the system. In some examples, “slightly” can refer to a deviation of less than a threshold percentage (e.g., about 1%, 2%, 5%, 10%, 20%, 1-5%, and/or 5-20%, etc.) of the reference condition or characteristic parameter. In some examples, “slightly” can refer to a deviation that does not substantially affect the performance of the optical system (e.g., wherein the deviation results in a change in a performance metric of less than a threshold percentage, such as about 1%, 2%, 5%, 10%, 20%, 1-5%, and/or 5-20%, etc.). In some examples, “slightly” can refer to a deviation that is within the tolerances of one or more downstream optical elements (e.g., a field facet mirror, a pupil facet mirror, a lithographic scanner, and/or any other suitable downstream element). As used herein, “slightly” can additionally or alternatively mean “not substantially” (e.g., “slightly greater than” can mean “greater than but not substantially greater than”; “no more than slightly greater than” can mean “not substantially greater than,” as in less than, equal to, or greater than but not substantially greater than). However, “slightly” can additionally or alternatively be interpreted in any other suitable manner.

As used herein, “slightly convergent” or “slightly divergent” (e.g., with respect to an input light beam) can refer to a beam having a divergence angle of less than a threshold angle from collimation (e.g., about 0.01 degrees, 0.05 degrees, 0.1 degrees, 0.2 degrees, 0.5 degrees, 1 degree, 2 degrees, 5 degrees, 0.01-0.1, 0.1-1, and/or 1-10 degrees, etc.). In some examples, the divergence angle can be less than a threshold percentage of a collection half-angle of the collector mirror (e.g., about 1%, 2%, 5%, 10%, 20%, 1-5%, and/or 5-20%, etc.). However, “slightly convergent” or “slightly divergent” can additionally or alternatively refer to any other suitable degree of convergence or divergence.

As used herein, “slightly exceed” (e.g., with respect to a bound on a hole size, a tolerance, and/or any other suitable parameter) can refer to exceeding the bound by less than a threshold percentage of the bound (e.g., about 1%, 2%, 5%, 10%, 20%, 1-5%, and/or 5-20%, etc.). In some examples, “slightly exceed” can refer to exceeding the bound by less than a threshold amount (e.g., about 0.1 mm, 0.2 mm, 0.5 mm, 1 mm, 2 mm, 5 mm, 0.1-1 mm, and/or 1-10 mm, etc.). However, “slightly exceed” can additionally or alternatively refer to any other suitable degree of exceedance.

### 4. Method of Use

### 4.1 Receiving a Light Beam

Receiving a light beam S310 preferably functions to receive a light input (e.g., EUV light for photolithography). S310 can include receiving, at a vacuum vessel housing a collector mirror and a replicator mirror, an input light beam from a light source. The light source preferably includes one or more free-electron lasers (FELs), but can additionally or alternatively include one or more synchrotrons, high-harmonic generation (HHG) sources, and/or any other suitable light source(s).

The input light beam preferably enters the vacuum vessel (e.g., from a beamline that connects the light source to the vacuum vessel). Within the vacuum vessel, the input light beam preferably propagates through a central hole of the collector mirror. The input light beam can propagate along (or substantially along) an optical axis of the collector mirror toward the replicator mirror.

However, S310 can additionally or alternatively include receiving any suitable light beam in any suitable manner.

### 4.2 Creating a Virtual Focus

Creating a virtual focus S320 preferably functions to simulate light emission from a point source (e.g., within the vacuum vessel). S320 preferably includes reflecting the input light beam toward the reflective surface of the collector mirror. S320 is preferably performed at the reflective surface of the replicator mirror, but can additionally or alternatively be performed at any other suitable location(s).

The reflective surface of the replicator mirror preferably reflects the input light beam such that the reflected light beam diverges with a virtual focus at or near a first point (e.g., a first focus of the collector mirror). The virtual focus can simulate light emission from a source at (and/or near) the first point (e.g., simulating a plasma source at the first point). In some examples, the virtual focus can have an angular distribution that is accepted by downstream optical elements (e.g., a field facet mirror, a pupil facet mirror, and/or any other suitable downstream optics) with substantially the same efficiency as light from a plasma source at the first point.

However, S320 can additionally or alternatively include any suitable reflection and/or redirection of the light in any suitable manner.

### 4.3 Delivering a Light Output

Delivering a light output S330 preferably functions to deliver the light to one or more downstream tools (e.g., lithographic tools such as scanners) via a light output point (e.g., intermediate focus point). S330 can include reflecting the reflected light beam toward a light output point (e.g., a second focus of the collector mirror, such as an intermediate focus point of a lithographic scanner). S330 is preferably performed at the reflective surface of the collector mirror, but can additionally or alternatively be performed at any other suitable location(s).

The reflective surface of the collector mirror preferably focuses the diverging reflected light toward the light output point. Delivering the light output can additionally include delivering the focused light to one or more lithographic tools (e.g., a scanner, a stepper, and/or any other suitable lithographic tool) via the light output point.

However, S330 can additionally or alternatively include delivering any suitable light in any suitable manner.

### 4.4 Additional Method Elements

The method can additionally or alternatively include one or more additional elements. For example, the method can include absorbing, at a beam dump, a portion of the input light beam that passes through a hole in the replicator mirror (e.g., light that the reflective surface of the replicator mirror does not intercept). Additionally or alternatively, the method can include maintaining a reduced pressure within the vacuum vessel (e.g., maintaining a pressure differential between the vessel interior and a beamline of the light source, such as via a differential pumping system). Additionally or alternatively, the method can include maintaining a buffer gas environment (e.g., a hydrogen environment at a partial pressure of about 0.1 to about 10 Pa) within the vacuum vessel. Additionally or alternatively, the method can include exposing a photolithographic resist to EUV light (e.g., delivered such as described above regarding S330) via one or more downstream optical elements (e.g., a field facet mirror, a pupil facet mirror, and/or any other suitable optical elements).

However, the method can additionally or alternatively include any other suitable elements in any suitable order.

### 5. Method of Fabrication

A method of fabrication for an optical system can include retrofitting an existing laser-produced plasma (LPP) light source (e.g., commercially-available LPP light source), fabricating an optical system using one or more components that are designed for (and/or identical to components of) an LPP light source, and/or any other suitable fabrication approach.

In a first variant, the method of fabrication can include retrofitting an existing LPP light source (e.g., commercially-available LPP light source). Retrofitting the LPP light source can include removing one or more LPP-specific components from the LPP light source (e.g., a tin droplet generator, a tin catch, a drive laser, a drive laser focusing module, and/or any other suitable LPP-specific components). Retrofitting the LPP light source can additionally or alternatively include installing a replicator mirror within a vacuum vessel of the LPP light source (e.g., between a collector mirror and a first focus of the collector mirror, such as at or near a location where a tin plasma was generated during LPP operation). This can optionally include mechanically connecting the replicator mirror to the vacuum vessel via one or more support members (e.g., arranged within one or more shadowed volumes). Retrofitting the LPP light source can optionally include connecting the vacuum vessel to a light source (e.g., a free-electron laser) via a beamline. The method can include retaining the collector mirror, the vacuum vessel, and/or one or more downstream optical elements (e.g., a field facet mirror) from the LPP light source.

In a second variant, the method of fabrication can include fabricating an optical system using one or more components that are designed for (and/or substantially identical to components of) an LPP light source (e.g., commercially-available LPP light source), such as without retrofitting an existing LPP light source. For example, the method can include obtaining a collector mirror that is substantially identical to a collector mirror of an LPP light source (e.g., a collector mirror having the same optical prescription, the same mounting interface geometry, and/or the same outer dimensions as a standard LPP collector mirror). The method can include obtaining a vacuum vessel that is substantially identical to a vacuum vessel of the LPP light source. The method can include installing a replicator mirror within the vacuum vessel (e.g., between the collector mirror and a first focus of the collector mirror). The method can include connecting the vacuum vessel to a light source (e.g., a free-electron laser) via a beamline. In some examples, the optical system can be fabricated to interface with one or more lithographic tools (e.g., scanners) that are designed to receive light from an LPP light source, such that the optical system can replace the LPP light source without modifying the lithographic tool. The method can include adapting the optical system for a particular scanner platform (e.g., selecting a replicator mirror shape, position, and/or size appropriate for the particular platform).

However, the method of fabrication can additionally or alternatively include fabricating the optical system in any other suitable manner, and/or can include any other suitable elements performed in any suitable manner.

### 6. Specific Examples

A numbered list of specific examples of the technology described herein are provided below. A person of skill in the art will recognize that the scope of the technology is not limited to and/or by these specific examples.

1. An optical system comprising: a vacuum vessel defining a vessel interior, the vessel interior fluidly isolated from an ambient environment surrounding the vacuum vessel; a collector mirror arranged within the vessel interior, the collector mirror comprising: a collector body; and a concave reflective surface bounding the collector body, the concave reflective surface defining a first focus at a first point and a second focus at a light output point; wherein the collector mirror defines a collector hole through the collector body and the concave reflective surface; a replicator mirror arranged within the vessel interior, the replicator mirror comprising: a replicator body; and a convex reflective surface bounding the replicator body, the convex reflective surface substantially defining a portion of a surface of rotation of a conic section, the conic section defining a virtual replicator focus substantially at the first point; wherein: the collector mirror defines an optical axis through the first point and the light output point, wherein the collector hole encircles the optical axis; the convex reflective surface defines a perimeter that encircles the optical axis; the replicator mirror is arranged between the collector mirror and the first point, wherein the convex reflective surface is disposed toward the concave reflective surface; and the first point is arranged between the collector mirror and the light output point.

2. The optical system of Specific Example 1, wherein the conic section is a parabola.

3. The optical system of Specific Example 1 or 2, wherein the conic section is a hyperbola, the hyperbola defining a second hyperbola focus at a point other than the first point.

4. The optical system of any one of Specific Examples 1-3, wherein the conic section is an ellipse, the ellipse defining a second ellipse focus at a point other than the first point.

5. The optical system of any one of Specific Examples 1-4, wherein the collector mirror is substantially identical to a standard collector mirror of a laser-produced plasma (LPP) light source for a commercially-available lithographic scanner.

6. The optical system of Specific Example 5, wherein the concave reflective surface is elliptical.

7. The optical system of Specific Example 5 or 6, wherein the first point corresponds to a location at which the commercially-available LPP light source generates a tin plasma.

8. The optical system of any one of Specific Examples 5-7, further comprising a field facet mirror arranged within the vacuum vessel, the field facet mirror opposing the collector mirror and the replicator mirror across the light output point, wherein the field facet mirror is substantially identical to a standard field facet mirror of the commercially-available lithographic scanner.

9. The optical system of any one of Specific Examples 5-8, wherein: the standard collector mirror defines a standard light output point within the LPP light source and defines a conical volume between the standard collector mirror and the standard light output point, the conical volume defining a perimeter on the standard collector mirror and an apex at the standard light output point; the LPP light source defines a standard shadowed volume within the conical volume, wherein, during LPP light source operation, extreme ultraviolet (EUV) light travels from the standard collector mirror to the standard light output point through the conical volume, and EUV light does not travel from the standard collector mirror to the standard light output point through the standard shadowed volume; the LPP light source defines a first arrangement comprising the standard collector mirror and the standard shadowed volume; and the optical system further comprises a support member mechanically connecting the replicator mirror to the vacuum vessel, the support member arranged within a shadowed volume, wherein a second arrangement comprising the collector mirror and the shadowed volume is substantially congruent with the first arrangement.

10. The optical system of Specific Example 9, wherein the support member comprises a first support member and a second support member extending from the replicator body in opposing directions across the optical axis, each arranged within a respective shadowed volume, wherein each respective second arrangement comprising the collector mirror and the respective shadowed volume is substantially congruent with the first arrangement.

11. The optical system of Specific Example 9, wherein the support member comprises a single cantilevered support member extending from the replicator body within the shadowed volume.

12. The optical system of any of the preceding Specific Examples, further comprising: a first cooling line defining a first interior; and a second cooling line defining a second interior; wherein the replicator body defines a cooling channel that fluidly couples the first interior to the second interior.

13. The optical system of Specific Example 12, wherein the cooling channel follows a spiral path.

14. The optical system of Specific Example 12 or 13, further comprising a heat exchanger arranged outside the vacuum vessel, the first cooling line and the second cooling line forming a cooling loop with the heat exchanger.

15. The optical system of any of the preceding Specific Examples, wherein the replicator mirror defines a replicator hole through the replicator body and the convex reflective surface, the replicator hole encircling the optical axis.

16. The optical system of Specific Example 15, further comprising a beam dump arranged substantially on the optical axis between the replicator mirror and the light output point.

17. The optical system of Specific Example 15 or 16, wherein: the replicator mirror defines a first focal length from a replicator vertex of the conic section to the virtual replicator focus; the concave reflective surface substantially defines a portion of a second surface of rotation of a second conic section, the second conic section defining a collector vertex; the collector mirror defines a second focal length from the collector vertex to the first point; the replicator hole defines a replicator hole diameter; the collector hole defines a collector hole diameter; a mirror hole diameter ratio is greater than or equal to a focal length ratio; the mirror hole diameter ratio is a quotient of the replicator hole diameter divided by the collector hole diameter; and the focal length ratio is a quotient of the first focal length divided by the second focal length.

18. The optical system of any one of Specific Examples 15-17, wherein: the replicator hole defines a replicator hole diameter; the collector hole defines a collector hole diameter; a mirror hole diameter ratio is a quotient of the replicator hole diameter divided by the collector hole diameter; and a focal length ratio is a quotient of a first focal length divided by a second focal length, the first focal length from a replicator vertex of the conic section to the virtual replicator focus, and the second focal length from a collector vertex to the first point; wherein the mirror hole diameter ratio is less than or equal to 125% of the focal length ratio.

19. The optical system of any one of Specific Examples 15-18, wherein the replicator hole is sized such that light diverging from a virtual source at the first point within a cone corresponding to the replicator hole, after reflecting from the concave reflective surface toward the light output point, is substantially blocked by the replicator body.

20. The optical system of any one of Specific Examples 15-19, wherein: the concave reflective surface substantially defines a portion of a second surface of rotation of a second conic section, the second conic section defining a collector vertex; the collector mirror defines: a first focal length f₁ from the collector vertex to the first point; and a second focal length f₂ from the collector vertex to the light output point; the replicator mirror defines a third focal length f₃ from a replicator vertex of the conic section to the virtual replicator focus; the convex reflective surface defines a replicator mirror diameter Dᵣₘ; the replicator hole defines a replicator hole diameter Dᵣₕ; and Dᵣₕ/Dᵣₘ is less than or equal to f₃f₂/f₁V, where V is a distance from the light output point to the replicator vertex.

21. The optical system of any one of Specific Examples 15-20, wherein the replicator hole defines a diameter of about 15 to about 20 mm.

22. The optical system of any of the preceding Specific Examples, wherein: the convex reflective surface comprises a first multilayer coating comprising molybdenum and silicon; and the concave reflective surface comprises a second multilayer coating comprising molybdenum and silicon.

23. The optical system of Specific Example 22, wherein at least one of the first multilayer coating or the second multilayer coating further comprises a ruthenium capping layer.

24. The optical system of Specific Example 22 or 23, wherein at least one of the first multilayer coating or the second multilayer coating further comprises boron carbide interlayers.

25. The optical system of any of the preceding Specific Examples, wherein the replicator body comprises at least one of: an aluminum alloy, silicon carbide, beryllium, Zerodur, or fused silica.

26. The optical system of any of the preceding Specific Examples, further comprising: a pupil facet mirror; and a field facet mirror arranged substantially on the optical axis, the field facet mirror opposing the collector mirror across the light output point, the field facet mirror arranged to receive light from the collector mirror via the light output point and to redirect the light toward the pupil facet mirror.

27. The optical system of any of the preceding Specific Examples, further comprising gaseous hydrogen contained within the vessel interior, the gaseous hydrogen defining a partial pressure of about 0.1 to 10 Pa.

28. The optical system of Specific Example 27, further comprising a differential pumping system arranged between the vessel interior and a beamline of a light source, wherein the differential pumping system maintains the beamline at a lower pressure than the vessel interior.

29. The optical system of any of the preceding Specific Examples, wherein a light beam enters the vessel interior along the optical axis through the collector hole and reflects from the convex reflective surface toward the concave reflective surface.

30. The optical system of Specific Example 29, wherein the light beam is generated by a free-electron laser.

31. The optical system of Specific Example 29 or 30, wherein the light beam is substantially collimated.

32. The optical system of any of the preceding Specific Examples, wherein the replicator mirror produces a virtual image substantially at the first point.

33. The optical system of any of the preceding Specific Examples, wherein the concave reflective surface defines a diameter of about 600 to about 750 mm.

34. The optical system of any of the preceding Specific Examples, wherein the collector hole defines a diameter of about 75 to about 125 mm.

35. The optical system of any of the preceding Specific Examples, wherein the convex reflective surface defines a diameter of about 75 to about 125 mm.

36. The optical system of any of the preceding Specific Examples, wherein a distance from a vertex of the replicator mirror to the first point is about 25 to about 45 mm.

37. The optical system of any of the preceding Specific Examples, wherein a distance from a vertex of the collector mirror to the first point is about 200 to about 250 mm.

38. The optical system of any of the preceding Specific Examples, wherein a distance from a vertex of the collector mirror to the light output point is about 1,300 to about 1,600 mm.

39. The optical system of any one of Specific Examples 1-38, wherein the optical system is fabricated by retrofitting a laser-produced plasma light source, comprising installing the replicator mirror within the vacuum vessel of the laser-produced plasma light source.

40. The optical system of any one of Specific Examples 1-39, wherein the optical system is configured to perform the method of any one of Specific Examples 41-62.

41. A method of providing light to a lithographic tool, the method comprising: at a vacuum vessel housing a collector mirror and a replicator mirror, the collector mirror comprising a concave reflective surface defining an optical axis: receiving a light beam from a free-electron laser, the light beam propagating substantially along the optical axis through a collector hole defined by the collector mirror, wherein the optical axis intersects a first focus of the collector mirror and a second focus of the collector mirror; at a convex reflective surface of the replicator mirror, reflecting the light beam toward the concave reflective surface such that the reflected light beam is divergent with a virtual focus substantially at the first focus of the collector mirror; and at the concave reflective surface, reflecting the reflected light beam substantially toward the second focus of the collector mirror.

42. The method of Specific Example 41, wherein the convex reflective surface substantially defines a portion of a surface of rotation of a conic section.

43. The method of Specific Example 41 or 42, wherein the light beam is substantially collimated, and wherein the convex reflective surface substantially defines a portion of a surface of rotation of a parabola having a focus substantially at the first focus.

44. The method of Specific Example 41 or 42, wherein the light beam is divergent, and wherein the convex reflective surface substantially defines a portion of a surface of rotation of a hyperbola having a focus substantially at the first focus.

45. The method of Specific Example 41 or 42, wherein the light beam is convergent, and wherein the convex reflective surface substantially defines a portion of a surface of rotation of an ellipse having a focus substantially at the first focus.

46. The method of Specific Example 41 or 42, wherein the convex reflective surface substantially defines a portion of a surface of rotation of an ellipse.

47. The method of any one of Specific Examples 41-46, wherein the light beam comprises extreme ultraviolet light.

48. The method of any one of Specific Examples 41-47, further comprising absorbing, at a beam dump arranged substantially on the optical axis between the replicator mirror and the second focus, a portion of the light beam that passes through a replicator hole of the replicator mirror.

49. The method of any one of Specific Examples 41-48, further comprising delivering the reflected light beam to a field facet mirror of a lithographic scanner via the second focus.

50. The method of Specific Example 49, further comprising exposing a photolithographic resist to a portion of the reflected light beam via the field facet mirror.

51. The method of any one of Specific Examples 41-50, further comprising maintaining a pressure differential between the vessel interior and a beamline of the free-electron laser via a differential pumping system.

52. The method of any one of Specific Examples 41-51, further comprising maintaining a hydrogen environment within the vessel interior at a partial pressure of about 0.1 to 10 Pa.

53. The method of any one of Specific Examples 41-52, wherein the concave reflective surface is elliptical, and wherein the first focus of the collector mirror corresponds to a location at which a laser-produced plasma light source generates a tin plasma.

54. The method of any one of Specific Examples 41-53, wherein the vacuum vessel and the collector mirror are substantially identical to a vacuum vessel and a collector mirror of a laser-produced plasma light source.

55. The method of Specific Example 54, further comprising mechanically supporting the replicator mirror within the vacuum vessel via a support member arranged in a volume that corresponds to a shadowed volume of the laser-produced plasma light source.

56. The method of any one of Specific Examples 41-55, wherein the convex reflective surface comprises a multilayer coating comprising molybdenum and silicon.

57. The method of any one of Specific Examples 41-56, wherein the concave reflective surface defines a diameter of about 600 to about 750 mm, and wherein the convex reflective surface defines a diameter of about 75 to about 125 mm.

58. The method of any one of Specific Examples 43-57, wherein the virtual focus is displaced along the optical axis from the first focus of the collector mirror.

59. The method of Specific Example 52, further comprising maintaining a pressure differential between the hydrogen environment and a beamline of the free-electron laser via a differential pumping system.

60. The method of any one of Specific Examples 41-59, further comprising cooling the replicator mirror by routing a coolant fluid through a cooling channel defined in the replicator body.

61. The method of any one of Specific Examples 41-60, performed using the optical system of any one of Specific Examples 1-40.

62. The method of any one of Specific Examples 41-60, further comprising retrofitting a laser-produced plasma light source, comprising installing the replicator mirror within the vacuum vessel of the laser-produced plasma light source.

63. The method of Specific Example 62, wherein retrofitting the laser-produced plasma light source further comprises removing a set of plasma-generating elements from the laser-produced plasma light source.

All references cited herein are incorporated by reference in their entirety, except to the extent that the incorporated material is inconsistent with the express disclosure herein, in which case the language in this disclosure controls.

As used herein, “substantially” or other words of approximation can be within a predetermined error threshold or tolerance of a metric, component, or other reference, and/or be otherwise interpreted.

Optional elements, which can be included in some variants but not others, are indicated in broken line in the figures. However, unbroken lines in the figures should not be interpreted to indicate that the depicted elements are essential or may not be omitted from variants of the invention.

Different subsystems and/or modules discussed above can be operated and controlled by the same or different entities. In the latter variants, different subsystems can communicate via: APIs (e.g., using API requests and responses, API keys, etc.), requests, and/or other communication channels. Communications between systems can be encrypted (e.g., using symmetric or asymmetric keys), signed, and/or otherwise authenticated or authorized.

Alternative embodiments implement the above methods and/or processing modules in non-transitory computer-readable media, storing computer-readable instructions that, when executed by a processing system, cause the processing system to perform the method(s) discussed herein. The instructions can be executed by computer-executable components integrated with the computer-readable medium and/or processing system. The computer-readable medium may include any suitable computer readable media such as RAMs, ROMs, flash memory, EEPROMs, optical devices (CD or DVD), hard drives, floppy drives, non-transitory computer readable media, or any suitable device. The computer-executable component can include a computing system and/or processing system (e.g., including one or more collocated or distributed, remote or local processors) connected to the non-transitory computer-readable medium, such as CPUs, GPUs, TPUS, microprocessors, or ASICs, but the instructions can alternatively or additionally be executed by any suitable dedicated hardware device.

Embodiments of the system and/or method can include every combination and permutation of the various system components and the various method processes, wherein one or more instances of the method and/or processes described herein can be performed asynchronously (e.g., sequentially), contemporaneously (e.g., concurrently, in parallel, etc.), or in any other suitable order by and/or using one or more instances of the systems, elements, and/or entities described herein. Components and/or processes of the following system and/or method can be used with, in addition to, in lieu of, or otherwise integrated with all or a portion of the systems and/or methods disclosed in the applications mentioned above, each of which are incorporated in their entirety by this reference.

The FIGURES illustrate the architecture, functionality and operation of possible implementations of systems, methods and computer program products according to preferred embodiments, example configurations, and variations thereof. In this regard, each block in the flowchart or block diagrams may represent a module, segment, step, or portion of code, which comprises one or more executable instructions for implementing the specified logical function(s). It should also be noted that, in some alternative implementations, the functions noted in the block can occur out of the order noted in the FIGURES. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

As a person skilled in the art will recognize from the previous detailed description and from the figures and claims, modifications and changes can be made to the preferred embodiments of the invention without departing from the scope of this invention defined in the following claims.

We claim:

1. An optical system comprising:
a vacuum vessel defining a vessel interior, the vessel interior fluidly isolated from an ambient environment surrounding the vacuum vessel;
a collector mirror arranged within the vessel interior, the collector mirror comprising:
a collector body; and
a concave reflective surface bounding the collector body, the concave reflective surface defining a first focus at a first point and a second focus at a light output point; wherein the collector mirror defines a collector hole through the collector body and the concave reflective surface;
a replicator mirror arranged within the vessel interior, the replicator mirror comprising:
a replicator body; and
a convex reflective surface bounding the replicator body, the convex reflective surface substantially defining a portion of a surface of rotation of a conic section, the conic section defining a virtual replicator focus substantially at the first point;
wherein:
the collector mirror defines an optical axis through the first point and the light output point, wherein the collector hole encircles the optical axis;
the convex reflective surface defines a perimeter that encircles the optical axis;
the replicator mirror is arranged between the collector mirror and the first point, wherein the convex reflective surface is disposed toward the concave reflective surface; and
the first point is arranged between the collector mirror and the light output point.

2. The optical system of claim 1, wherein the conic section is a parabola.

3. The optical system of claim 1, wherein the collector mirror is substantially identical to a standard collector mirror of a laser-produced plasma (LPP) light source for a commercially-available lithographic scanner.

4. The optical system of claim 3, further comprising a field facet mirror arranged within the vacuum vessel, the field facet mirror opposing the collector mirror and the replicator mirror across the light output point, wherein the field facet mirror is substantially identical to a standard field facet mirror of the commercially-available lithographic scanner.

5. The optical system of claim 3, wherein:
the standard collector mirror defines a standard light output point within the LPP light source and defines a conical volume between the standard collector mirror and the standard light output point, the conical volume defining a perimeter on the standard collector mirror and an apex at the standard light output point;
the LPP light source defines a standard shadowed volume within the conical volume, wherein, during LPP light source operation, extreme ultraviolet (EUV) light travels from the standard collector mirror to the standard light output point through the conical volume, and EUV light does not travel from the standard collector mirror to the standard light output point through the standard shadowed volume;
the LPP light source defines a first arrangement comprising the standard collector mirror and the standard shadowed volume; and
the optical system further comprises a support member mechanically connecting the replicator mirror to the vacuum vessel, the support member arranged within a shadowed volume, wherein a second arrangement comprising the collector mirror and the shadowed volume is substantially congruent with the first arrangement.

6. The optical system of claim 1, further comprising:
a first cooling line defining a first interior; and
a second cooling line defining a second interior; wherein the replicator body defines a cooling channel that fluidly couples the first interior to the second interior.

7. The optical system of claim 1, wherein the replicator mirror defines a replicator hole through the replicator body and the convex reflective surface, the replicator hole encircling the optical axis.

8. The optical system of claim 7, further comprising a beam dump arranged substantially on the optical axis between the replicator mirror and the light output point, wherein:
the replicator mirror defines a first focal length from a replicator vertex of the conic section to the virtual replicator focus;
the concave reflective surface substantially defines a portion of a second surface of rotation of a second conic section, the second conic section defining a collector vertex;
the collector mirror defines a second focal length from the collector vertex to the first point;
the replicator hole defines a replicator hole diameter;
the collector hole defines a collector hole diameter;
a mirror hole diameter ratio is greater than or equal to a focal length ratio;
the mirror hole diameter ratio is a quotient of the replicator hole diameter divided by the collector hole diameter; and
the focal length ratio is a quotient of the first focal length divided by the second focal length.

9. The optical system of claim 7, wherein:
the concave reflective surface substantially defines a portion of a second surface of rotation of a second conic section, the second conic section defining a collector vertex;
the collector mirror defines:
first focal length f₁ from the collector vertex to the first point; and
a second focal length f₂ from the collector vertex to the light output point;
the replicator mirror defines a third focal length f₃ from a replicator vertex of the conic section to the virtual replicator focus;
the convex reflective surface defines a replicator mirror diameter Dᵣₘ;
the replicator hole defines a replicator hole diameter Dᵣₕ; and
$$\frac{{D}_{rh}}{{D}_{rm}} \leq \frac{{f}_{2} \times {f}_{3}}{{f}_{1} \times V} ,$$
where V is a distance from the light output point to the replicator vertex.

10. The optical system of claim 1, wherein:
the convex reflective surface comprises a first multilayer coating comprising molybdenum and silicon; and
the concave reflective surface comprises a second multilayer coating comprising molybdenum and silicon.

11. The optical system of claim 1, further comprising:
a pupil facet mirror; and
a field facet mirror (FFM) arranged substantially on the optical axis, the FFM opposing the collector mirror across the light output point, the field facet mirror arranged to receive light from the collector mirror via the light output point and to redirect the light toward the pupil facet mirror.

12. The optical system of claim 1, further comprising gaseous hydrogen contained within the vessel interior, the gaseous hydrogen defining a partial pressure of about 0.1 to 10 Pa.

13. A method of providing light to a lithographic tool, the method comprising:
at a vacuum vessel housing a collector mirror and a replicator mirror, the collector mirror comprising a concave reflective surface defining an optical axis: receiving a light beam from a free-electron laser, the light beam propagating substantially along the optical axis through a collector hole defined by the collector mirror, wherein the optical axis intersects a first focus of the collector mirror and a second focus of the collector mirror;
at a convex reflective surface of the replicator mirror, reflecting the light beam toward the concave reflective surface such that the reflected light beam is divergent with a virtual focus substantially at the first focus of the collector mirror; and
at the concave reflective surface, reflecting the reflected light beam substantially toward the second focus of the collector mirror.

14. The method of claim 13, wherein the convex reflective surface substantially defines a portion of a surface of rotation of an ellipse.

15. The method of claim 13, wherein:
the light beam is substantially collimated; and
the convex reflective surface substantially defines a portion of a surface of rotation of a parabola having a focus substantially at the first focus.

16. The method of claim 13, wherein the light beam comprises extreme ultraviolet light.

17. The method of claim 13, further comprising absorbing, at a beam dump arranged substantially on the optical axis between the replicator mirror and the second focus, a portion of the light beam that passes through a replicator hole of the replicator mirror.

18. The method of claim 13, further comprising delivering the reflected light beam to a field facet mirror of a lithographic scanner via the second focus.

19. The method of claim 18, further comprising exposing a photolithographic resist to a portion of the reflected light beam via the field facet mirror.

20. The method of claim 13, further comprising maintaining a pressure differential between the vessel interior and a beamline of the free-electron laser via a differential pumping system.
